(19) United States
(12) Patent Application Publication
(10) Pub. No.: US 2024/0204157 A1
(43) Pub. Date: Jun. 20, 2024

(54) DISPLAY DEVICE

(71) Applicant: LG Display Co., Ltd., Seoul (KR)

(72) Inventors: Daeyoung SEO, Seoul (KR); Hun JANG, Paju-si (KR)

(21) Appl. No.: 18/511,595

(22) Filed: Nov. 16, 2023

(30) Foreign Application Priority Data
Dec. 16, 2022 (KR) 10-2022-0177272

(51) Int. Cl. H01L 33/62; H01L 25/16; H01L 33/58

(52) U.S. Cl. CPC H01L 33/62; H01L 25/167; H01L 33/58

(57) ABSTRACT

A display device disclosed herein includes a first assembly electrode and a second assembly electrode which are disposed on each of the plurality of sub pixels and are spaced apart from each other. The device includes a first and second protrusions on the first and second assembly electrodes, respectively. The device includes a light emitting diode between the first and second protrusions. The device includes a first reflective pattern on a side surface of the first protrusion and a second reflective pattern on a side surface of the second protrusion. The device includes a first contact electrode which is disposed on the first protrusion and the first reflective pattern and is electrically connected to the first assembly electrode. The device includes a second contact electrode which is disposed on the second protrusion and the second reflective pattern and is electrically connected to the second assembly electrode.

### CROSS-REFERENCE TO RELATED APPLICATIONS

This application claims the priority of Korean Patent Application No. 10-2022-0177272 filed on Dec. 16, 2022, in the Korean Intellectual Property Office, the disclosure of which is incorporated herein by reference.

### BACKGROUND

### Technical Field

The present disclosure relates to a display device, and more particularly, to a display device which self-assembles a light emitting diode (LED).

### Description of the Related Art

As display devices which are used for a monitor of a computer, a television, or a cellular phone, there are an organic light emitting display (OLED) device which is a self-emitting device and a liquid crystal display (LCD) device which requires a separate light source.

An applicable range of the display device is diversified to personal digital assistants as well as monitors of computers and televisions and a display device with a large display area and a reduced volume and weight is being studied.

Further, in recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance may be displayed.

### BRIEF SUMMARY

Various embodiments of the present disclosure provide a display device with an improved luminous efficiency by increasing an amount of light in a front direction of a self-assembled light emitting diode.

Various embodiments of the present disclosure provide a display device which is capable of repairing a defective light emitting diode, above a planarization layer disposed on the light emitting diode, to easily repair the defective light emitting diode.

Various embodiments of the present disclosure provide a display device with reduced power consumption in which a contact electrode and a reflective pattern are connected to reduce a resistance of a wiring line and an electrode to which a low potential power voltage is applied.

Various embodiments of the present disclosure provide a display device in which a space for disposing a redundancy light emitting diode is removed to implement a high resolution.

The technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate including a plurality of sub pixels; a first assembly electrode and a second assembly electrode which are disposed on each of the plurality of sub pixels and are spaced apart from each other; a first protrusion and a second protrusion disposed on the first assembly electrode and the second assembly electrode; a light emitting diode disposed between the first protrusion and the second protrusion; a first reflective pattern which is disposed on a side surface of the first protrusion opposite to the light emitting diode; a second reflective pattern which is disposed on a side surface of the second protrusion opposite to the light emitting diode; a first contact electrode which is disposed on the first protrusion and the first reflective pattern and is electrically connected to the first assembly electrode; and a second contact electrode which is disposed on the second protrusion and the second reflective pattern and is electrically connected to the second assembly electrode.

According to another aspect of the present disclosure, a display device includes a substrate including a plurality of sub pixels; a first assembly electrode and a second assembly electrode which are disposed on each of the plurality of sub pixels and are spaced apart from each other; a first protrusion which is disposed on the first assembly electrode and includes a top surface and a side surface disposed on a different plane from the top surface; a second protrusion which is disposed on the second assembly electrode and includes a top surface and a side surface disposed on a different plane from the top surface; a light emitting diode disposed between the first protrusion and the second protrusion; a first reflective pattern disposed on a side surface of the first protrusion; a second reflective pattern disposed on a side surface of the second protrusion; a first contact electrode which is disposed on the first protrusion and the first reflective pattern and is electrically connected to the first assembly electrode; and a second contact electrode which is disposed on the second protrusion and the second reflective pattern and is electrically connected to the second assembly electrode. The side surface of the first protrusion on which the first reflective pattern is disposed and the side surface of the second protrusion on which the second reflective pattern is disposed are opposite to the light emitting diode.

Other detailed matters of the exemplary embodiments are included in the detailed description and the drawings.

According to the exemplary embodiment, an amount of light in a front direction of the light emitting diode may be increased.

According to the exemplary embodiment of the present disclosure, the defective light emitting diode may be easily repaired above a planarization layer disposed on the light emitting diode.

According to the exemplary embodiment of the present disclosure, the repair process may be performed above the light emitting diode so that a space for disposing a redundancy light emitting diode may be removed.

According to the exemplary embodiment of the present disclosure, the contact electrode and the reflective pattern are connected to reduce a resistance for the low potential power voltage which is applied to the contact electrode and the reflective pattern.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is an enlarged plan view of a display device according to an exemplary embodiment of the present disclosure;

FIG. 2B is a cross-sectional view taken along the lines A-A′ and B-B′ of FIG. 2A;

FIGS. 3A to 3D are views for explaining a manufacturing process of a display device according to an exemplary embodiment of the present disclosure;

FIG. 4 is a cross-sectional view of a display device according to another exemplary embodiment of the present disclosure;

FIG. 5A is a cross-sectional view of a display device according to Comparative Embodiment 1;

FIG. 5B is a cross-sectional view of a display device according to Comparative Embodiment 2.

FIG. 5C is a cross-sectional view of a display device according to Comparative Embodiment 3;

FIG. 6A is an enlarged plan view of a display device according to still another exemplary embodiment of the present disclosure;

FIG. 6B is a cross-sectional view taken along C-C′ of FIG. 6A;

FIG. 7A is an enlarged plan view of a display device according to still another exemplary embodiment of the present disclosure;

FIG. 7B is a cross-sectional view taken along D-D′ of FIG. 7A;

FIG. 8A is an enlarged plan view of a display device according to still another exemplary embodiment of the present disclosure;

FIG. 8B is a cross-sectional view taken along E-E′ of FIG. 8A; and

FIG. 9 is an enlarged plan view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, number of elements, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including,’ ‘having,’ ‘consist of’ used herein are generally intended to allow other components to be added unless the terms are used with the term ‘only.’ Any references to singular may include plural unless expressly stated otherwise.

Components are interpreted to include an ordinary error range even if not expressly stated.

When the position relation between two parts is described using the terms such as ‘on,’ ‘above,’ ‘below,’ ‘next,’ one or more parts may be positioned between the two parts unless the terms are used with the term ‘immediately’ or ‘directly.’

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

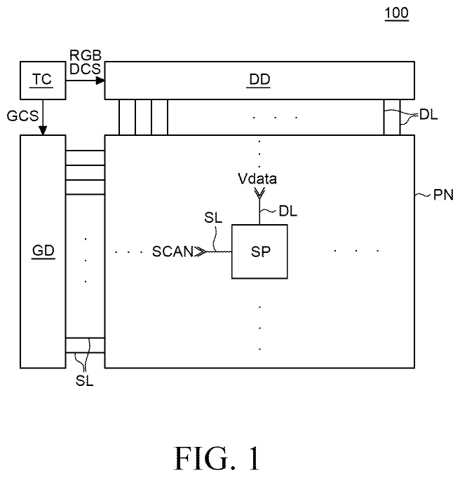

FIG. 1 is a schematic diagram of a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The display panel PN is a configuration for displaying images to the user and includes the plurality of sub pixels SP. In the display panel PN, the plurality of scan lines SL and the plurality of data lines DL intersect each other, and the plurality of sub pixels SP is connected to the scan lines SL and the data lines DL, respectively. In addition, even though it is not illustrated in the drawing, each of the plurality of sub pixels SP may be connected to a high potential power line, a low potential power line, and a reference line.

The plurality of sub pixels SP is a minimum unit which configures a screen and each of the plurality of sub pixels SP includes a light emitting diode and a pixel circuit for driving the light emitting diode. The plurality of light emitting diodes may be defined in different manners depending on the type of the display panel PN. For example, when the display panel PN is an inorganic light emitting display panel, the light emitting diode may be a light emitting diode (LED) or a micro light emitting diode (micro LED).

The gate driver GD supplies a plurality of scan signals SCAN to a plurality of scan lines SL in accordance with a plurality of gate control signals GCS supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data RGB input from the timing controller TC in accordance with a plurality of data control signals DCS supplied from the timing controller TC into a data voltage Vdata using a reference gamma voltage. The data driver DD may supply the converted data voltage Vdata to the plurality of data lines DL.

The timing controller TC aligns image data RGB input from the outside to supply the aligned image data to the data driver DD. The timing controller TC may generate a gate control signal GCS and a data control signal DCS using synchronization signals input from the outside, such as a dot clock signal, a data enable signal, and horizontal/vertical synchronization signals. The timing controller TC supplies the generated gate control signal GCS and data control signal DCS to the gate driver GD and the data driver DD, respectively, to control the gate driver GD and the data driver DD.

Hereinafter, a plurality of sub pixels SP of a display panel PN of a display device 100 according to an exemplary embodiment of the present disclosure will be described in more detail.

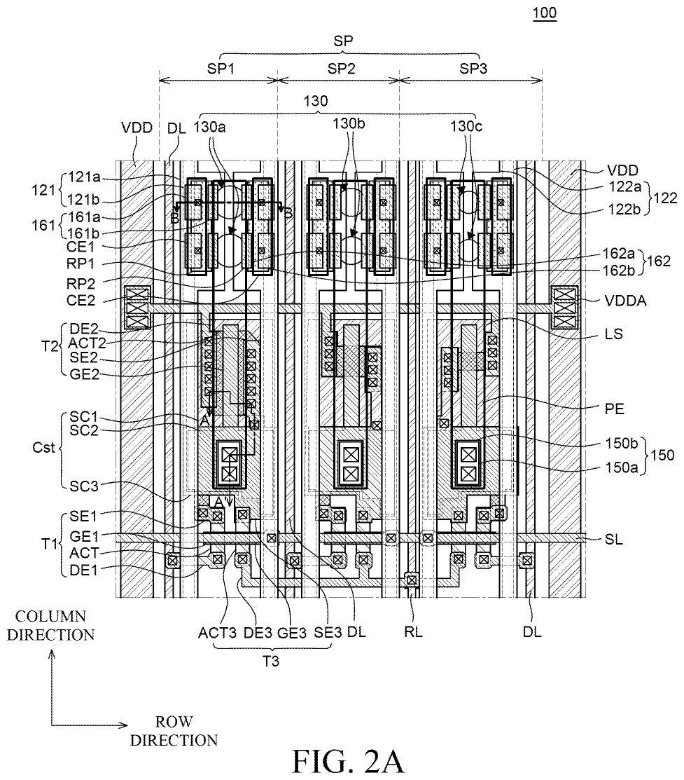

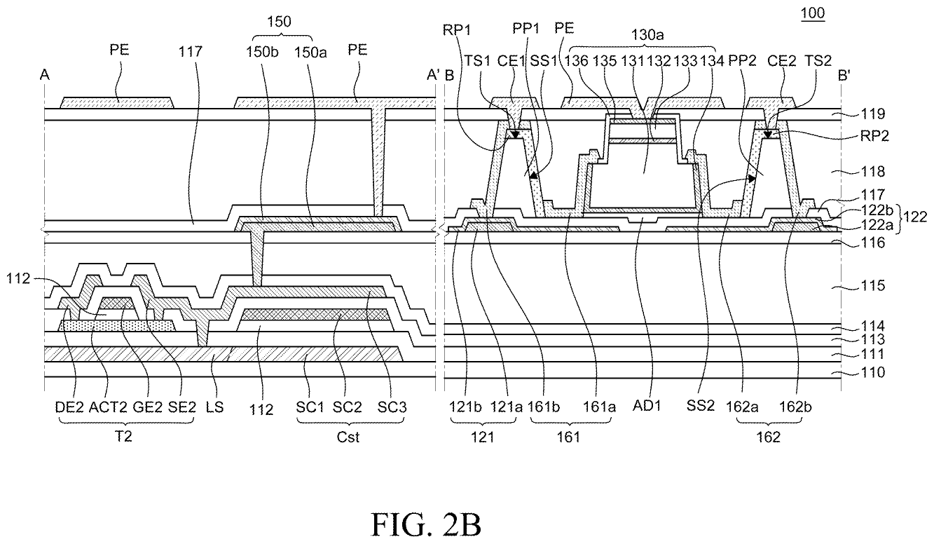

FIG. 2A is an enlarged plan view of a display device according to an exemplary embodiment of the present disclosure. FIG. 2B is a cross-sectional view taken along A-A′ and B-B′ of FIG. 2A. Referring to FIGS. 2A and 2B, each of the plurality of sub pixels SP includes a first transistor T1, a second transistor T2, a third transistor T3, a storage capacitor Cst, and one or more light emitting diodes 130. For the convenience of description, in FIG. 2A, hatching of a first assembly electrode 121, a second assembly electrode 122, the light emitting diode 130, a pixel electrode PE, a first connection electrode CE1, and a second connection electrode CE2 is omitted.

Referring to FIGS. 2A and 2B, the plurality of sub pixels SP includes a first sub pixel SP1, a second sub pixel SP2, and a third sub pixel SP3. Each of the first sub pixel SP1, the second sub pixel SP2, and the third sub pixel SP3 includes a light emitting diode 130 and a circuit to independently emit light. For example, the first sub pixel SP1 is a red sub pixel, the second sub pixel SP2 is a green sub pixel, and the third sub pixel SP3 may be a blue sub pixel, but it is not limited thereto.

The display panel PN includes a substrate 110, a buffer layer 111, a gate insulating layer 112, an interlayer insulating layer 113, a first passivation layer 114, a first planarization layer 115, a second passivation layer 116, a third passivation layer 117, a second planarization layer 118, and a fourth passivation layer 119.

First, the substrate 110 is a component for supporting various components included in the display device 100 and may be formed of an insulating material. For example, the substrate 110 may be formed of glass or resin. Further, the substrate 110 may also be configured to include polymer or plastic or may be formed of a material having flexibility.

A high potential power line VDD, a plurality of data lines DL, a reference line RL, a light shielding layer LS, and a first capacitor electrode SC1 are disposed on the substrate 110.

The high potential power line VDD is a wiring line which transmits a high potential power voltage to each of the plurality of sub pixels SP. The plurality of high potential power lines VDD may transmit the high potential power voltage to the second transistor T2 of each of the plurality of sub pixels SP. The high potential power line VDD may extend along a column direction between the plurality of sub pixels SP. For example, the high potential power line VDD may be disposed to extend along a column direction between the first sub pixel SP1 and the third sub pixel SP3. The high potential power line VDD may transmit a high potential power voltage to each of the plurality of sub pixels SP disposed in the row direction through an auxiliary high potential power line VDDA to be described below.

The plurality of data lines DL is wiring lines which transmit the data voltage Vdata to each of the plurality of sub pixels SP. The plurality of data lines DL may be connected to the first transistor T1 of each of the plurality of sub pixels SP. The plurality of data lines DL may extend along a column direction between the plurality of sub pixels SP. For example, a data line DL extended between the first sub pixel SP1 and the high potential power line VDD in the column direction transmits a data voltage Vdata to the first sub pixel SP1. A data line DL disposed between the first sub pixel SP1 and the second sub pixel SP2 transmits a data voltage Vdata to the second sub pixel SP2. Further, a data line DL disposed between the third sub pixel SP3 and the high potential power line VDD may transmit a data voltage Vdata to the third sub pixel SP3.

The reference line RL is a wiring line which transmits a reference voltage to each of the plurality of sub pixels SP. The reference line RL may be connected to the third transistor T3 of each of the plurality of sub pixels SP. The reference line RL may extend along a column direction between the plurality of sub pixels SP. For example, the reference line RL may extend along a column direction between the second sub pixel SP2 and the third sub pixel SP3. A third drain electrode DE3 of the third transistor T3 of each of the first sub pixel SP1, the second sub pixel SP2, and the third sub pixel SP3 adjacent to the reference line RL extends in the row direction to be electrically connected to the reference line RL.

The light shielding layer LS is disposed on the substrate 110 in each of the plurality of sub pixels SP. The light shielding layer LS blocks light which is incident to the transistor from the lower portion of the substrate 110 to minimize a leakage current. For example, the light shielding layer LS may block light incident to a second active layer ACT2 of the second transistor T2 which is a driving transistor.

In each of the plurality of sub pixels SP, a first capacitor electrode SC1 is disposed on the substrate 110. The first capacitor electrode SC1 may form a storage capacitor Cst together with the other capacitor electrode. The first capacitor electrode SC1 may be integrally formed with the light shielding layer LS.

A buffer layer 111 is disposed on the high potential power line VDD, the plurality of data lines DL, the reference line RL, the light shielding layer LS, and the first capacitor electrode SC1. The buffer layer 111 may reduce permeation of moisture or impurities through the substrate 110. The buffer layer 111 may be configured by a single layer or a plurality of layers of silicon oxide (SiOx) or silicon nitride (SiNx), but is not limited thereto. However, the buffer layer 111 may be omitted depending on a type of substrate 110 or a type of transistor, but is not limited thereto.

First, the first transistor T1 is disposed on the buffer layer 111 in each of the plurality of sub pixels SP. The first transistor T1 is a transistor which transmits a data voltage Vdata to the second gate electrode GE2 of the second transistor T2. The first transistor T1 may be turned on by a scan signal SCAN from the scan line SL, and a data voltage Vdata from the data line DL may be transmitted to the second gate electrode GE2 of the second transistor T2 through the turned-on first transistor T1. Accordingly, the first transistor T1 may be referred to as a switching transistor.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 may be formed of a semiconductor material such as an oxide semiconductor, amorphous silicon, or polysilicon, but is not limited thereto.

The gate insulating layer 112 is disposed on the first active layer ACT1. The gate insulating layer 112 is an insulating layer for insulating the first active layer ACT1 from the first gate electrode GE1, and may be configured by a single layer or a plurality of layers of silicon oxide (SiOx) or silicon nitride (SiNx), but is not limited thereto.

The first gate electrode GE1 is disposed on the gate insulating layer 112. The first gate electrode GE1 may be electrically connected to the scan line SL. The first gate electrode GE1 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the first gate electrode GE1. A contact hole is formed in the interlayer insulating layer 113 to allow the first source electrode SE1 and the first drain electrode DE1 to connect to the first active layer ACT1. The interlayer insulating layer 113 is an insulating layer for protecting components below the first interlayer insulating layer 113, and may be configured by a single layer or a plurality of layers of silicon oxide (SiOx) or silicon nitride (SiNx), but is not limited thereto.

A first source electrode SE1 and a first drain electrode DE1 which are electrically connected to the first active layer ACT1 are disposed on the interlayer insulating layer 113. The first drain electrode DE1 may be connected to the data line DL and the first active layer ACT1, and the first source electrode SE1 may be connected to the first active layer ACT1 and the second gate electrode GE2 of the second transistor T2. The first source electrode SE1 and the first drain electrode DE1 may be configured by a conductive material, such as copper (Cu), aluminum (Al), molybdenum (Mo), nickel (Ni), titanium (Ti), chrome (Cr), or an alloy thereof, but are not limited thereto.

The second transistor T2 is disposed on the buffer layer 111 in each of the plurality of sub pixels SP. The second transistor T2 is a transistor which supplies a driving current to the light emitting diode 130. The second transistor T2 is turned on to control the current flowing to the light emitting diode 130. Accordingly, the second transistor T2 which controls the driving current may be referred to as a driving transistor.

The second transistor T2 includes a second active layer ACT2, a second gate electrode GE2, a second source electrode SE2, and a second drain electrode DE2.

The second active layer ACT2 is disposed on the buffer layer 111. The second active layer ACT2 may be formed of a semiconductor material such as an oxide semiconductor, amorphous silicon, or polysilicon, but is not limited thereto.

The gate insulating layer 112 is disposed on the second active layer ACT2 and the second gate electrode GE2 is disposed on the gate insulating layer 112. The second gate electrode GE2 may be electrically connected to the first source electrode SE1 of the first transistor T1. The second gate electrode GE2 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the second gate electrode GE2 and the second source electrode SE2 and the second drain electrode DE2 which are electrically connected to the second active layer ACT2 are disposed on the interlayer insulating layer 113. The second drain electrode DE2 may be electrically connected to the second active layer ACT2 and the high potential power line VDD, and the second source electrode SE2 may be electrically connected to the second active layer ACT2 and the light emitting diode 130. The second source electrode SE2 and the second drain electrode DE2 may be configured by a conductive material, such as copper (Cu), aluminum (Al), molybdenum (Mo), nickel (Ni), titanium (Ti), chrome (Cr), or an alloy thereof, but are not limited thereto.

The third transistor T3 is disposed on the buffer layer 111 in each of the plurality of sub pixels SP. The third transistor T3 is a transistor for compensating for a threshold voltage of the second transistor T2. The third transistor T3 is connected between the second source electrode SE2 of the second transistor T2 and the reference line RL. The third transistor T3 is turned on to transmit the reference voltage to the second source electrode SE2 of the second transistor T2 to sense a threshold voltage of the second transistor T2. Accordingly, the third transistor T3 which senses a characteristic of the second transistor T2 may be referred to as a sensing transistor.

The third transistor T3 includes a third active layer ACT3, a third gate electrode GE3, a third source electrode SE3, and a third drain electrode DE3.

The third active layer ACT3 is disposed on the buffer layer 111. The third active layer ACT3 may be formed of a semiconductor material such as an oxide semiconductor, amorphous silicon, or polysilicon, but is not limited thereto.

The gate insulating layer 112 is disposed on the third active layer ACT3 and the third gate electrode GE3 is disposed on the gate insulating layer 112. The third gate electrode GE3 may be electrically connected to the scan line SL. The third gate electrode GE3 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the third gate electrode GE3 and the third source electrode SE3 and the third drain electrode DE3 which are electrically connected to the third active layer ACT3 are disposed on the interlayer insulating layer 113. The third drain electrode DE3 is electrically connected to the third active layer ACT3 and the reference line RL and the third source electrode SE3 may be electrically connected to the third active layer ACT3 and the second source electrode SE2 of the second transistor T2. The third source electrode SE3 and the third drain electrode DE3 may be configured by a conductive material, such as copper (Cu), aluminum (Al), molybdenum (Mo), nickel (Ni), titanium (Ti), chrome (Cr), or an alloy thereof, but are not limited thereto.

Next, the second capacitor electrode SC2 is disposed on the gate insulating layer 112. The second capacitor electrode SC2 is one of electrodes which form the storage capacitor Cst and may be disposed to overlap the first capacitor electrode SC1. The second capacitor electrode SC2 is integrally formed with the second gate electrode GE2 of the second transistor T2 to be electrically connected to the second gate electrode GE2. The first capacitor electrode SC1 and the second capacitor electrode SC2 may be disposed to be spaced apart from each other with the buffer layer 111 and the gate insulating layer 112 therebetween.

The plurality of scan lines SL, the auxiliary high potential power line VDDA, and a third capacitor electrode SC3 are disposed on the interlayer insulating layer 113.

First, the scan line SL is a wiring line which transmits the scan signal SCAN to each of the plurality of sub pixels SP. The scan line SL may extend in the row direction while traversing the plurality of sub pixels SP. The scan line SL may be electrically connected to the first gate electrode GE1 of the first transistor T1 and the third gate electrode GE3 of the third transistor T3 of each of the plurality of sub pixels SP.

The auxiliary high potential power line VDDA is disposed on the interlayer insulting layer 113. The auxiliary high potential power line VDDA may be disposed to extend in the row direction to traverse the plurality of sub pixels SP. The auxiliary high potential power line VDDA may be electrically connected to the high potential power line VDD extending in the column direction and the second drain electrode DE2 of the second transistor T2 of each of the plurality of sub pixels SP disposed along the row direction.

The third capacitor electrode SC3 is disposed on the interlayer insulating layer 113. The third capacitor electrode SC3 is an electrode which forms the storage capacitor Cst and may be disposed to overlap the first capacitor electrode SC1 and the second capacitor electrode SC2. The third capacitor electrode SC3 is integrally formed with the second source electrode SE2 of the second transistor T2 to be electrically connected to the second source electrode SE2. The second source electrode SE2 may be electrically connected to the first capacitor electrode SC1 through a contact hole formed in the interlayer insulating layer 113 and the buffer layer 111. Therefore, the first capacitor electrode SC1 and the third capacitor electrode SC3 may be electrically connected to the second source electrode SE2 of the second transistor T2.

The storage capacitor Cst stores a potential difference between the second gate electrode GE2 and the second source electrode SE2 of the second transistor T2 while the light emitting diode 130 emits light, so that a constant current is supplied to the light emitting diode 130. The storage capacitor Cst includes the first capacitor electrode SC1, the second capacitor electrode SC2, and the third capacitor electrode SC3 to store a voltage between the second gate electrode GE2 and the second source electrode SE2 of the second transistor T2. The first capacitor electrode SC1 is formed on the substrate 110 and is connected to the second source electrode SE2, and the second capacitor electrode SC2 is formed on the buffer layer 111 and the gate insulating layer 112 and is connected to the second gate electrode GE2. The third capacitor electrode SC3 is formed on the interlayer insulating layer 113 and is connected to the second source electrode SE2.

The first passivation layer 114 is disposed on the first transistor T1, the second transistor T2, the third transistor T3, and the storage capacitor Cst. The first passivation layer 114 is an insulating layer for protecting components below the first passivation layer 114 and may be configured by a single layer or a plurality of layers of silicon oxide (SiOx) or silicon nitride (SiNx), but is not limited thereto.

The first planarization layer 115 is disposed on the first passivation layer 114. The first planarization layer 115 may planarize an upper portion of the substrate 110 on which the plurality of transistors T1, T2, and T3 and the storage capacitor Cst are disposed. The first planarization layer 115 may be configured by a single layer or a plurality of layers, and for example, may be formed of an acrylic organic material, but is not limited thereto.

The second passivation layer 116 is disposed on the first planarization layer 115. The second passivation layer 116 is an insulating layer for protecting components below the second passivation layer 116 and may be configured by a single layer or a plurality of layers of silicon oxide (SiOx) or silicon nitride (SiNx), but is not limited thereto.

A connection unit 150, a first assembly electrode 121, and a second assembly electrode 122 are disposed on the second passivation layer 116.

First, the connection unit 150 is disposed in each of the plurality of sub pixels SP. The connection unit 150 is an electrode which electrically connects the second transistor T2 and the pixel electrode PE. The connection unit 150 may be electrically connected to the second source electrode SE2 which also serves as the third capacitor electrode SC3 through a contact hole formed in the second passivation layer 116, the first planarization layer 115, and the first passivation layer 114.

The connection unit 150 may have a plurality of layers structure formed by a first connection layer 150a and a second connection layer 150b. The first connection layer 150a is disposed on the second passivation layer 116 and the second connection layer 150b which covers the first connection layer 150a is disposed. The second connection layer 150b may be disposed to enclose all a top surface and side surfaces of the first connection layer 150a. The second connection layer 150b is formed of a material which is more resistant to corrosion than the first connection layer 150a so that when the display device 100 is manufactured, the short defect due to the migration between the first connection layer 150a and the adjacent wiring line may be minimized. For example, the first connection layer 150a is formed of a conductive material, such as copper (Cu) or chrome (Cr), and the second connection layer 150b may be formed of molybdenum (Mo) or titanium molybdenum (MoTi), but are not limited thereto.

The first assembly electrode 121 and the second assembly electrode 122 are disposed on the second passivation layer 116. The first assembly electrode 121 and the second assembly electrode 122 are wiring lines which transmit the low potential power voltage to the light emitting diode 130. Therefore, the first assembly electrode 121 and the second assembly electrode 122 may be referred to as low potential power lines. The plurality of first assembly electrodes 121 and second assembly electrodes 122 are disposed in each of the plurality of sub pixels SP and may be spaced apart from each other to extend in the column direction. For example, one pair of first assembly electrode 121 and second assembly electrode 122 which are spaced apart from each other with a predetermined interval may be disposed in each of the first sub pixel SP1, the second sub pixel SP2, and the third sub pixel SP3.

In the meantime, the first assembly electrode 121 and the second assembly electrode 122 may serve as electrodes for self-assembling the light emitting diode 130. For example, when the display device 100 is manufactured, the first assembly electrode 121 and the second assembly electrode 122 form an electric field to self-assemble the light emitting diode 130.

Each of the first assembly electrode 121 and the second assembly electrode 122 includes conductive layers 121a and 122a and clad layers 121b and 122b. That is, the first assembly electrode 121 includes the first conductive layer 121a and the first clad layer 121b, and the second assembly electrode 122 includes the second conductive layer 122a and the second clad layer 122b.

The conductive layers 121a and 122a of each of the first assembly electrode 121 and the second assembly electrode 122 are disposed on the second passivation layer 116, and the clad layers 121b and 122b are disposed to cover all top surfaces and side surfaces of the conductive layers 121a and 122a on the second passivation layer 116. For example, the conductive layers 121a and 122a may be formed of a conductive material, such as copper (Cu) and chrome (Cr). The clad layers 121b and 122b may be formed of a material which is more resistant to corrosion than the conductive layers 121a and 122a, for example, molybdenum (Mo) or titanium molybdenum (MoTi), but is not limited thereto.

The clad layers 121b and 122b of each of the first assembly electrode 121 and the second assembly electrode 122 may be disposed to protrude toward an area in which the plurality of light emitting diodes 130 is disposed. Therefore, the clad layer 121b and 122b are configured to overlap an area in which the plurality of light emitting diodes 130 is disposed so that the first assembly electrode 121 and the second assembly electrode 122 may be configured to serve as electrodes for self-assembling the light emitting diode 130.

The third passivation layer 117 is disposed on the connection unit 150, the first assembly electrode 121, and the second assembly electrode 122. The third passivation layer 117 is an insulating layer for protecting components below the third passivation layer 117 and may be configured by a single layer or a plurality of layers of silicon oxide (SiOx) or silicon nitride (SiNx), but is not limited thereto.

A first protrusion PP1 and a second protrusion PP2 are disposed on the third passivation layer 117. The first protrusion PP1 and the second protrusion PP2 are disposed on the third passivation layer 117 so as to overlap the first assembly electrode 121 and the second assembly electrode 122, respectively. That is, the first protrusion PP1 and the second protrusion PP2 are disposed above the first assembly electrode 121 and the second assembly electrode 122, respectively.

Referring to FIG. 2B, the first protrusion PP1 and the second protrusion PP2 are spaced apart from each other and are configured to expose the third passivation layer 117 in an area in which the light emitting diode 130 is disposed. Therefore, the light emitting diode 130 may be disposed between the first protrusion PP1 and the second protrusion PP2. At this time, a side surface which is opposite to an area in which the plurality of light emitting diode 130 is disposed, among side surfaces of the first protrusion PP1 and the second protrusion PP2, may be an inclined surface. That is, the first protrusion PP1 has a first side surface SS1 that is facing the light emitting diode 130. The second protrusion PP2 has a second side surface SS2 that is facing the light emitting diode 130 and the second side surface SS2 is opposite the first side surface SS1. The both side surfaces of the first protrusion PP1 and the both side surfaces of the second protrusion PP2 may be inclined side surfaces as shown in FIG. 2B. Accordingly, in one embodiment, the cross-section of the first and second protrusions PP1, PP2 can have a trapezoid-like cross-section.

The first protrusion PP1 and the second protrusion PP2 may be configured by a single layer or a plurality of layers, and for example, may be formed of an acrylic organic material, but are not limited thereto.

A first reflective pattern RP1 and a second reflective pattern RP2 are disposed on side surfaces and a part of the top surfaces TS1, TS2 of the first protrusion PP1 and the second protrusion PP2. Specifically, the first reflective pattern RP1 and the second reflective pattern RP2 are disposed on a part of the top surfaces of the first protrusion PP1 and the second protrusion PP2 and a side surface opposite to an area in which the plurality of light emitting diodes 130 is disposed, among side surfaces of the first protrusion PP1 and the second protrusion PP2.

The first reflective pattern RP1 and the second reflective pattern RP2 are disposed on the inclined surface which is a side surface opposite to the area in which the plurality of light emitting diodes 130 is disposed, of the side surfaces of the first protrusion PP1 and the second protrusion PP2. Therefore, the first reflective pattern RP1 and the second reflective pattern RP2 may be disposed on both sides of the light emitting diode 130 and reflect light emitted to the side surface and the rear surface, among light emitted from the light emitting diode 130, to the front surface of the display device 100.

For example, the first reflective pattern RP1 and the second reflective pattern RP2 may be formed of a metal material including aluminum (Al), silver (Ag), gold (Au), copper (Cu), magnesium (Mg), molybdenum (Mo), or nickel (Ni) and may be formed of a reflective metal material, but are not limited thereto.

In the meantime, the first reflective pattern RP1 and the second reflective pattern RP2 are disposed on the third passivation layer 117 to be spaced apart from the light emitting diode 130 so as not to be in contact with the light emitting diode 130 to be formed later. The first reflective pattern RP1 and the second reflective pattern RP2 may be connected to the first assembly electrode 121 and the second assembly electrode 122 disposed below the first reflective pattern RP1 and the second reflective pattern RP2, respectively. Therefore, the low potential power voltage may be applied to the first reflective pattern RP1 and the second reflective pattern RP2.

Next, the plurality of light emitting diodes 130 is disposed on the third passivation layer exposed from the first protrusion PP1 and the second protrusion PP2. One or more light emitting diodes 130 are disposed in one sub pixel SP. The light emitting diode 130 is an element which emits light by the current. The light emitting diode 130 may include a light emitting diode 130 which emits red light, green light, and blue light and implements various color light including white by a combination thereof. Further, various color light may be implemented using the light emitting diode 130 which emits specific color light and a light conversion member which converts light from the light emitting diode 130 into another color light. The light emitting diode 130 is electrically connected between the second transistor T2 and the first assembly electrode 121 and the second assembly electrode 122 to be supplied with a driving current from the second transistor T2 to emit light.

At this time, the plurality of light emitting diodes 130 disposed in one sub pixel SP may be connected in parallel. That is, one electrode of each of the plurality of light emitting diodes 130 is connected to the source electrode of the second transistor T2 and the other electrode may be connected to the same assembly electrodes 121 and 122.

In the meantime, the light emitting diode 130 disposed in each of the plurality of sub pixels SP may have a different structure from each other. For example, the light emitting element 130 may include a first light emitting diode 130a, a second light emitting diode 130b, and a third light emitting diode 130c. The first light emitting diode 130a may be disposed in the first sub pixel SP, among the plurality of sub pixels SP, the second light emitting diode 130b may be disposed in the second sub pixel SP2, among the plurality of sub pixels SP, and the third light emitting diode 130c may be disposed in the third sub pixel SP3, among the plurality of sub pixels SP. However, the type of the light emitting diode 130 is illustrative and only any one of the first light emitting diode 130a, the second light emitting diode 130b, and the third light emitting diode 130c is used as the light emitting diode 130 or another type of light emitting diode 130 may also be used, but is not limited thereto. Even though in FIG. 2A, for the convenience of description, it is illustrated that two light emitting diodes 130 are disposed in each of the plurality of sub pixels SP, the number of light emitting diodes 130 which are disposed in each of the plurality of sub pixels SP is not limited thereto.

Referring to FIG. 2A, the light emitting diode 130 disposed in each of the plurality of sub pixels SP may have a different size from each other. For example, the first light emitting diode 130a disposed in the first sub pixel SP1, among the plurality of sub pixels SP, may be larger than the second light emitting diode 130b disposed in the second sub pixel SP2 and the third light emitting diode 130c disposed in the third sub pixel SP3. Further, the second light emitting diode 130b disposed in the second sub pixel SP2 may be larger than the third light emitting diode 130c disposed in the third sub pixel SP3, but it is not limited thereto.

Referring to FIG. 2B, each of the plurality of light emitting diodes 130 includes a first semiconductor layer 131, an emission layer 132, a second semiconductor layer 133, a first electrode 134, a second electrode 135, and an encapsulation layer 136.

The first semiconductor layer 131 is disposed on the third passivation layer 117 and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers formed by doping p-type or n-type impurities into a material, such as gallium nitride (GaN), indium aluminum phosphide (InAlP), or gallium arsenide (GaAs). The p-type impurity may be magnesium (Mg), zinc (Zn), and beryllium (Be), and the n-type impurity may be silicon (Si), germanium (Ge), and tin (Sn), but are not limited thereto.

A part of the first semiconductor layer 131 may be disposed to outwardly protrude from the second semiconductor layer 133. A top surface of the first semiconductor layer 131 may be formed by a part overlapping a bottom surface of the second semiconductor layer 133 and a part disposed at an outside of the bottom surface of the second semiconductor layer 133. However, sizes and shapes of the first semiconductor layer 131 and the second semiconductor layer 133 may be modified in various forms, but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN) or gallium nitride (GaN), but is not limited thereto.

The first electrode 134 which encloses a bottom surface and side surfaces of the first semiconductor layer 131 is disposed. The first electrode 134 is an electrode which electrically connects the first light emitting diode 130a and the assembly electrodes 121 and 122. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the top surface of the second semiconductor layer 133. The second electrode 135 is an electrode which electrically connects a pixel electrode PE to be described below and the second semiconductor layer 133. The second electrode 135 may be formed of a conductive material, for example, a transparent conductive material, such as indium tin oxide (ITO) or indium zinc oxide (IZO), but is not limited thereto.

The encapsulation layer 136 which encloses at least a part of the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. The encapsulation layer 136 may be disposed so as to cover the emission layer 132, a part of a side surface of the first semiconductor layer 131 adjacent to the emission layer 132, and a part of a side surface of the second semiconductor layer 133 adjacent to the emission layer 132. The first electrode 134 and the second electrode 135 may be exposed from the encapsulation layer 136 and contact electrodes 161 and 162 and a pixel electrode PE to be formed later and the first electrode 134 and the second electrode 135 may be electrically connected.

An adhesive layer AD1 is disposed between the plurality of light emitting diodes 130 and the third passivation layer 117. The adhesive layer AD1 may be an organic film which temporarily fixes the light emitting diode 130 during the self-assembling process of the light emitting diode 130. When the display device 100 is manufactured, if an organic film which covers the light emitting diode 130 is formed, a part of the organic film is filled in a space between the light emitting diode 130 and the third passivation layer 117 to temporarily fix the light emitting diode 130 onto the third passivation layer 117. Thereafter, even though the organic film is removed, a part of the organic film permeated under the light emitting diode 130 remains without being removed to become an adhesive layer AD1. The adhesive layer AD1 may be formed of an organic material, for example, an acrylic organic material, but is not limited thereto.

The first contact electrode 161 is disposed on the side surface of the light emitting diode 130 and on the first protrusion PP1 and the first reflective pattern RP1, and the second contact electrode 162 is disposed on the side surface of the light emitting diode 130 and on the second protrusion PP2 and the second reflective pattern RP2.

The first contact electrode 161 is an electrode which electrically connects the light emitting diode 130 and the first assembly electrode 121. Therefore, the first contact electrode 161 is electrically connected to the first electrode 134 of the light emitting diode 130 and the first assembly electrode 121. The second contact electrode 162 is an electrode which electrically connects the light emitting diode 130 and the second assembly electrode 122. Therefore, the second contact electrode 162 is electrically connected to the first electrode 134 of the light emitting diode 130 and the second assembly electrode 122.

The first contact electrode 161 is disposed to extend from the side surface of the light emitting diode 130 to be in contact with the first reflective pattern RP1. The first contact electrode 161 is electrically connected to the first assembly electrode 121 through the contact hole formed in the third passivation layer 117. Therefore, the first contact electrode 161 may electrically connect the light emitting diode 130 and the first assembly electrode 121.

The second contact electrode 162 is disposed to extend from the side surface of the light emitting diode 130 to be in contact with the second reflective pattern RP2. The second contact electrode 162 is electrically connected to the second assembly electrode 122 through the contact hole formed in the third passivation layer 117. Therefore, the second contact electrode 162 may electrically connect the light emitting diode 130 and the second assembly electrode 122.

The first contact electrode 161 and the second contact electrode 162 include the first parts 161a and 162a and the second parts 161b and 162b, respectively.

The first part 161a of the first contact electrode 161 is in contact with the first electrode 134 of the light emitting diode 130 and the first reflective pattern RP1. The second part 161b of the first contact electrode 161 is spaced apart from the first part 161a and is in contact with the first reflective pattern RP1 and the first assembly electrode 121. That is, the first part 161a and the second part 161b of the first contact electrode 161 are configured to be spaced apart from each other and be in contact with the first reflective pattern RP1. Therefore, the first contact electrode 161 may be configured to expose a part of the first reflective pattern RP1 and may electrically connect the light emitting diode 130 and the first assembly electrode 121.

The first part 162a of the second contact electrode 162 is in contact with the first electrode 134 of the light emitting diode 130 and the second reflective pattern RP2. The second part 162b of the second contact electrode 162 is spaced apart from the first part 162a and is in contact with the second reflective pattern RP2 and the second assembly electrode 122. That is, the first part 162a and the second part 162b of the second contact electrode 162 are configured to be spaced apart from each other and be in contact with the second reflective pattern RP2. Therefore, the second contact electrode 162 may be configured to electrically connect the light emitting diode 130 and the second assembly electrode 122 while exposing a part of the second reflective pattern RP2.

The first contact electrode 161 and the second contact electrode 162 may be configured by a conductive material such as copper (Cu), aluminum (Al), molybdenum (Mo), nickel (Ni), titanium (Ti), chrome (Cr), or an alloy thereof, but is not limited thereto.

In the meantime, the reflectance of the first contact electrode 161 and the second contact electrode 162 may be lower than the reflectance of the first reflective pattern RP1 and the second reflective pattern RP2. Therefore, the first reflective pattern RP1 and the second reflective pattern RP2 may be configured to reflect more light emitted from the light emitting diode 130 than the first contact electrode 161 and the second contact electrode 162, but are not limited thereto.

Next, the second planarization layer 118 is disposed on the light emitting diode 130, the first contact electrode 161, and the second contact electrode 162. The second planarization layer 118 planarizes an upper portion of the substrate 110 on which the light emitting diode 130 is disposed and may fix the light emitting diode 130 onto the substrate 110 together with the adhesive layer AD1. The second planarization layer 118 may be configured by a single layer or a plurality of layers, and for example, may be formed of an acrylic organic material, but is not limited thereto.

The fourth passivation layer 119 is disposed on the second planarization layer 118. The fourth passivation layer 119 is an insulating layer for protecting components below the fourth passivation layer 119 and may be configured by a single layer or a double layer of silicon oxide (SiOx) or silicon nitride (SiNx), but is not limited thereto. At this time, the fourth passivation layer 119 is not an essential configuration and may be omitted depending on the design.

In the meantime, referring to FIG. 2B, the second planarization layer 118 is disposed to expose a top surface of the first contact electrode 161, a top surface of the second contact electrode 162, a top surface and a part of side surface of the light emitting diode 130. The fourth passivation layer 119 is configured to cover the exposed top surface of the first contact electrode 161, top surface of the second contact electrode 162, top surface and part of side surface of the light emitting diode 130 to cover the first contact electrode 161, the second contact electrode 162, and the light emitting diode 130. However, the second planarization layer 118 and the fourth passivation layer 119 may be disposed to cover all the top surface of the first contact electrode 161, the top surface of the second contact electrode 162, and the top surface of the light emitting diode 130 to fully cover the light emitting diode 130, the first contact electrode 161, and the second contact electrode 162. However, it is not limited thereto.

The pixel electrode PE, the first connection electrode CE1, and the second connection electrode CE2 are disposed on the fourth passivation layer 119.

The pixel electrode PE is an electrode for electrically connecting the plurality of light emitting diodes 130 and the connection unit 150. The pixel electrode PE is electrically connected to the plurality of light emitting diodes 130. Specifically, the pixel electrode PE may be electrically connected to the light emitting diode 130, the connection unit 150, and the second transistor T2 through the contact hole formed in the second planarization layer 118 and the fourth passivation layer 119. Accordingly, the second electrode 135 of the light emitting diodes 130, the connection unit 150, and the second source electrode SE2 of the second transistor T2 may be electrically connected to each other by means of the pixel electrode PE. The pixel electrode PE may be formed of a conductive material, for example, a transparent conductive material, such as indium tin oxide (ITO) or indium zinc oxide (IZO), but is not limited thereto.

The first connection electrode CE1 is disposed on the second planarization layer 118 and the fourth passivation layer 119 and is electrically connected to the first contact electrode 161. The first connection electrode CE1 is a configuration which is electrically connected to the first assembly electrode 121 to provide a portion to be connected to the first assembly electrode 121 above the second planarization layer 118 and the fourth passivation layer 119.

Specifically, the first connection electrode CE1 is connected to the first contact electrode 161 through a contact hole formed in the second planarization layer 118 and the fourth passivation layer 119. The first contact electrode 161 is electrically connected to the first assembly electrode 121. Therefore, the first connection electrode CE1 is electrically connected to the first assembly electrode 121 so that consequently, the first connection electrode CE1 disposed above the second planarization layer 118 and the fourth passivation layer 119 may provide electrical connection to the first assembly electrode 121 through the first connection electrode CE1.

The second connection electrode CE2 is disposed on the second planarization layer 118 and the fourth passivation layer 119 and is electrically connected to the second contact electrode 162. The second connection electrode CE2 is a configuration which is electrically connected to the second assembly electrode 122 to provide a portion to be connected to the second assembly electrode 122 above the second planarization layer 118 and the fourth passivation layer 119.

Specifically, the second connection electrode CE2 is connected to the second contact electrode 162 through a contact hole formed in the second planarization layer 118 and the fourth passivation layer 119. The second contact electrode 162 is electrically connected to the second assembly electrode 122. Therefore, the second connection electrode CE2 is electrically connected to the second assembly electrode 122 so that consequently, the second connection electrode CE2 disposed above the second planarization layer 118 and the fourth passivation layer 119 may provide electrical connection to the second assembly electrode 122 through the second connection electrode CE2.

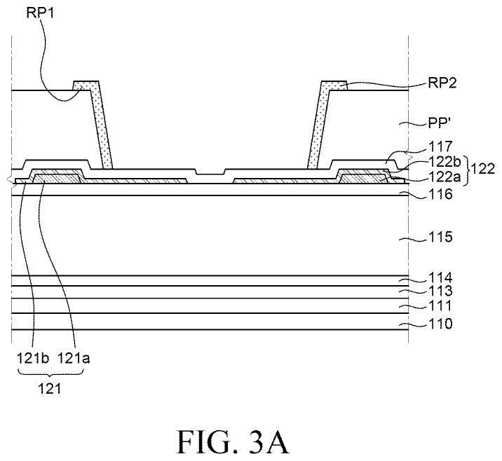

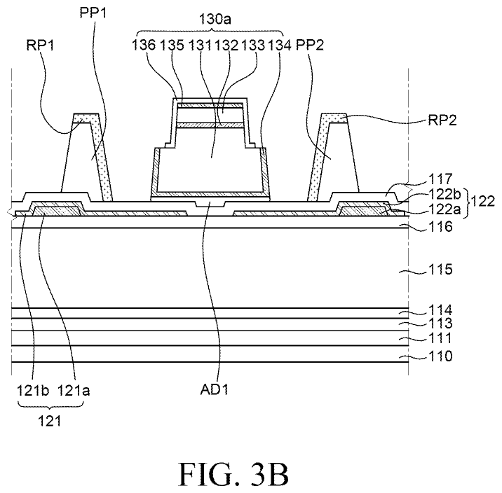

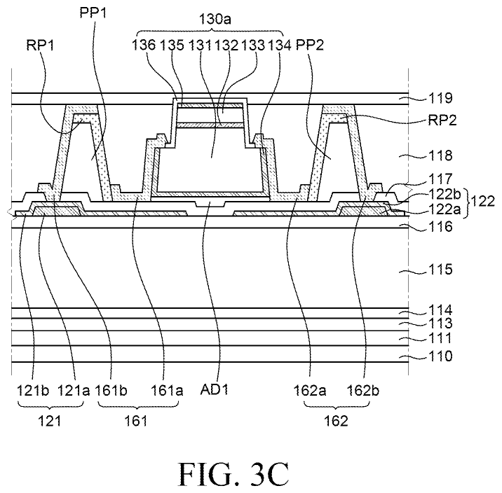

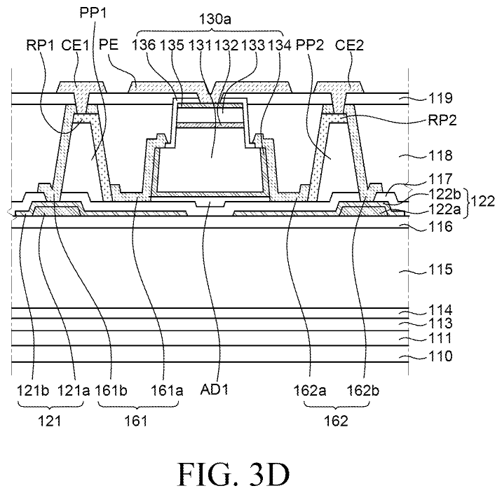

Hereinafter, a manufacturing process of a display device 100 according to an exemplary embodiment of the present disclosure will be described in more detail with reference to FIGS. 3A to 3D.

FIGS. 3A to 3D are views for explaining a manufacturing process of a display device according to an exemplary embodiment of the present disclosure.

First, referring to FIG. 3A, a buffer layer 111, an interlayer insulating layer 113, a first passivation layer 114, a first planarization layer 115, and a second passivation layer 116 are sequentially formed on a substrate and a first assembly electrode 121 and a second assembly electrode 122 are formed on the second passivation layer 116.

The first assembly electrode 121 and the second assembly electrode 122 are applied with different voltages from each other during the manufacturing process of the display device 100 to form an electrical field to serve as assembly electrodes for assembling the light emitting diode 130. After completing the manufacturing process of the display device 100, the same low potential power voltage is applied to the first assembly electrode 121 and the second assembly electrode 122 so that the first assembly electrode 121 and the second assembly electrode 122 may serve as one pair of low potential power lines.

Next, a third passivation layer 117 is formed on the first assembly electrode 121 and the second assembly electrode 122 and an organic layer PP′ having an opening is formed on the third passivation layer 117. The opening of the organic layer PP′ may correspond to an area in which the light emitting diode 130 is self-assembled.

A first reflective pattern RP1 and a second reflective pattern RP2 are formed on a side surface and a part of a top surface of the organic layer PP′ so as to be opposite to an area in which the light emitting diode 130 is self-assembled. For example, the first reflective pattern RP1 and the second reflective pattern RP2 may be formed of a reflective metal material.

A side surface of the organic layer PP′ on which the first reflective pattern RP1 and the second reflective pattern RP2 are disposed is formed as an inclined surface. Therefore, the first reflective pattern RP1 and the second reflective pattern RP2 may reflect light emitted to the side surface and a rear surface of the light emitting diode 130 to a front direction of the display device 100.

Referring to FIG. 3B, a first protrusion PP1 and a second protrusion PP2 are formed below the first reflective pattern RP1 and the second reflective pattern RP2 by patterning the organic layer PP′. The first protrusion PP1 and the second protrusion PP2 may be formed by removing a part of the organic layer PP′ in which the first reflective pattern RP1 and the second reflective pattern RP2 are not disposed. The organic layer PP′ may be removed, for example, by dry etching, but is not limited thereto.

In the meantime, during the manufacturing process of the display device 100 according to the exemplary embodiment of the present disclosure, the first reflective pattern RP1 and the second reflective pattern RP2 may be utilized as a mask for patterning the first protrusion PP1 and the second protrusion PP2. Therefore, a separate mask for patterning the first protrusion PP1 and the second protrusion PP2 may be omitted and a number of processes for forming the first protrusion PP1 and the second protrusion PP2 may be also reduced. Accordingly, in the display device 100 according to the exemplary embodiment of the present disclosure, the manufacturing process of the display device may be simplified.

The light emitting diode 130 is self-assembled between the first protrusion PP1 and the second protrusion PP2. For example, during the self-assembling process of the light emitting diode 130, different voltages are applied to the first assembly electrode 121 and the second assembly electrode 122 to form an electric field, and the light emitting diode 130 which is dielectrically polarized by the electric field moves to a specific direction or is fixed by dielectrophoresis (DEP), that is, the electric field. Therefore, the light emitting diode 130 may be self-assembled between the first protrusion PP1 and the second protrusion PP2, but is not limited thereto. At this time, the first reflective pattern RP1 and the second reflective pattern RP2 are electrically floated so that the first reflective pattern RP1 and the second reflective pattern RP2 may not interfere with the self-assembling process.

Referring to FIG. 3C, the first contact electrode 161 is formed on the side surface of the light emitting diode 130 and on the first protrusion PP1 and the first reflective pattern RP1, and the second contact electrode 162 is formed on the side surface of the light emitting diode 130 and on the second protrusion PP2 and the second reflective pattern RP2.

The first contact electrode 161 is an electrode for electrically connecting the light emitting diode 130 and the first assembly electrode 121, and the second contact electrode 162 is an electrode for electrically connecting the light emitting diode 130 and the second assembly electrode 122.

The first contact electrode 161 includes a first part 161a which is in contact with the first electrode 134 of the light emitting diode 130 and the first reflective pattern RP1 and a second part 161b which is spaced apart from the first part 161a and is in contact with the first reflective pattern RP1 and the first assembly electrode 121. Therefore, the first contact electrode 161 may be configured to expose a part of the first reflective pattern RP1 and electrically connect the light emitting diode 130 and the first assembly electrode 121.

The second contact electrode 162 includes a first part 162a which is in contact with the first electrode 134 of the light emitting diode 130 and the second reflective pattern RP2, and a second part 162b which is spaced apart from the first part 162a and is in contact with the second reflective pattern RP2 and the second assembly electrode 122. Therefore, the second contact electrode 162 may be configured to expose a part of the second reflective pattern RP2 and may electrically connect the light emitting diode 130 and the second assembly electrode 122.

Next, the second planarization layer 118 is formed on the light emitting diode 130, the first contact electrode 161, and the second contact electrode 162. The second planarization layer 118 planarizes an upper portion of the substrate 110 on which the light emitting diode 130 is disposed and may fix the light emitting diode 130 onto the substrate 110.

A fourth passivation layer 119 is formed on the second planarization layer 118. The fourth passivation layer 119 may be formed of an insulating material and be disposed to protect configurations below the fourth passivation layer 119.

Referring to FIG. 3C, the second planarization layer 118 is disposed to expose parts of a top surface of the first contact electrode 161, a top surface of the second contact electrode 162, a top surface and a side surface of the light emitting diode 130. The fourth planarization layer 119 is configured to cover parts of the exposed top surface of the first contact electrode 161, top surface of the second contact electrode 162, top surface and a side surface of the light emitting diode 130 to cover the first contact electrode 161, the second contact electrode 162, and the light emitting diode 130. Next, the first connection electrode CE1, the pixel electrode PE, and the second connection electrode CE to be formed later may be disposed on top surfaces of the first contact electrode 161, the second contact electrode 162, and the light emitting diode 130 which are exposed from the second planarization layer 118. However, it is not limited thereto.

However, the second planarization layer 118 and the fourth passivation layer 119 may be disposed to cover all the top surface of the first contact electrode 161, the top surface of the second contact electrode 162, and the top surface of the light emitting diode 130 to fully cover the light emitting diode 130, the first contact electrode 161, and the second contact electrode 162. However, the exemplary embodiment of the present disclosure is not limited thereto.

In the meantime, a first adhesive layer AD1 is disposed between the light emitting diode 130 and the third passivation layer 117. The first adhesive layer AD1 may be formed by a part of an organic film which temporarily fixes the light emitting diode 130 during the self-assembling process of the light emitting diode 130, which remains without being removed. For example, the organic film which covers and temporarily fixes the light emitting diode 130 during the self-assembling process may be also filled in a space between the light emitting diode 130 and the third passivation layer 117. Thereafter, even though the organic film is removed, a part of the organic film permeated under the light emitting diode 130 remains without being removed to form the first adhesive layer AD1, but is not limited thereto.

Referring to FIG. 3D, the pixel electrode PE, the first connection electrode CE1, and the second connection electrode CE2 are formed on the fourth passivation layer 119.

The pixel electrode PE may be connected to the light emitting diode 130 through a contact hole formed in the second planarization layer 118 and the fourth passivation layer 119. Accordingly, the pixel electrode PE may electrically connect the second electrode 135 of the light emitting diodes 130, the connection unit 150, and the second source electrode SE2 of the second transistor T2 to each other.

The first connection electrode CE1 and the second connection electrode CE2 may be electrically connected to the first contact electrode 161 and the second contact electrode 162 through a contact hole formed in the second planarization layer 118 and the fourth passivation layer 119. In the meantime, the first connection electrode CE1 and the second connection electrode CE2 may be formed of the same material by the same process as the pixel electrode, but are not limited thereto.

In the display device 100 according to the exemplary embodiment of the present disclosure, the first reflective pattern RP1 and the second reflective pattern RP2 are disposed on both sides of the self-assembled light emitting diode 130 to increase an amount of light in the front direction of the light emitting diode 130.

Specifically, the first reflective pattern RP1 and the second reflective pattern RP2 are disposed on the inclined surface which is a side surface opposite to the area in which the plurality of light emitting diodes 130 is disposed, of the side surfaces of the first protrusion PP1 and the second protrusion PP2. Therefore, the first reflective pattern RP1 and the second reflective pattern RP2 may be disposed on both sides of the light emitting diode 130. The first reflective pattern RP1 and the second reflective pattern RP2 are formed of a reflective metal material. Therefore, among light emitted from the light emitting diode 130, light emitted to a side surface and a rear surface of the light emitting diode 130 may be reflected to the front direction of the display device 100 by the first reflective pattern RP1 and the second reflective pattern RP2 disposed on both sides of the light emitting diode 130. Therefore, the first reflective pattern RP1 and the second reflective pattern RP2 may increase an amount of light in the front direction of the light emitting diode 130 by minimizing the loss of light emitted from the light emitting diode 130 to the side surface and a rear surface of the light emitting diode 130. Accordingly, in the display device 100 according to the exemplary embodiment of the present disclosure, the first reflective pattern RP1 and the second reflective pattern RP2 are disposed on both sides of the self-assembled light emitting diode 130 to increase an amount of light in the front direction of the light emitting diode 130 and improve the luminous efficiency of the light emitting diode. Accordingly, in the display device 100 according to the exemplary embodiment of the present disclosure, a display device 100 with a high efficiency and a low power in which the luminous efficiency is improved to reduce the power consumption may be provided.

In the display device 100 according to the exemplary embodiment of the present disclosure, the first connection electrode CE1 and the second connection electrode CE2 for electrical connection with the first assembly electrode 121 and the second assembly electrode 122 are disposed above the fourth passivation layer 119. Therefore, the defective light emitting diode may be configured to be repaired above the fourth passivation layer 119.

Specifically, the first connection electrode CE1 and the second connection electrode CE2 disposed on the second planarization layer 118 and the fourth passivation layer 119 may be electrically connected to each of the first contact electrode 161 and the second contact electrode 162 through a contact hole formed in the second planarization layer 118 and the fourth passivation layer 119. The first contact electrode 161 is electrically connected to the first assembly electrode 121 and the second contact electrode 162 is electrically connected to the second assembly electrode 122. Accordingly, the electrical connection with the first assembly electrode 121 and the second assembly electrode 122 may be provided through each of the first connection electrode CE1 and the second connection electrode CE2. For example, when a defective light emitting diode 130 needs to be repaired, an additional light emitting diode for repair is electrically connected to the first connection electrode CE1 and/or the second connection electrode CE2 disposed on the fourth passivation layer 119. Therefore, the added light emitting diode and the first connection electrode CE1 and/or the second connection electrode CE2 may be electrically connected. Therefore, the defective light emitting diode may be repaired above the second planarization layer 118 and the fourth passivation layer 119 without adding a process of forming a separate contact hole in the second planarization layer 118 and the fourth passivation layer 119 for repairing the defective light emitting diode.

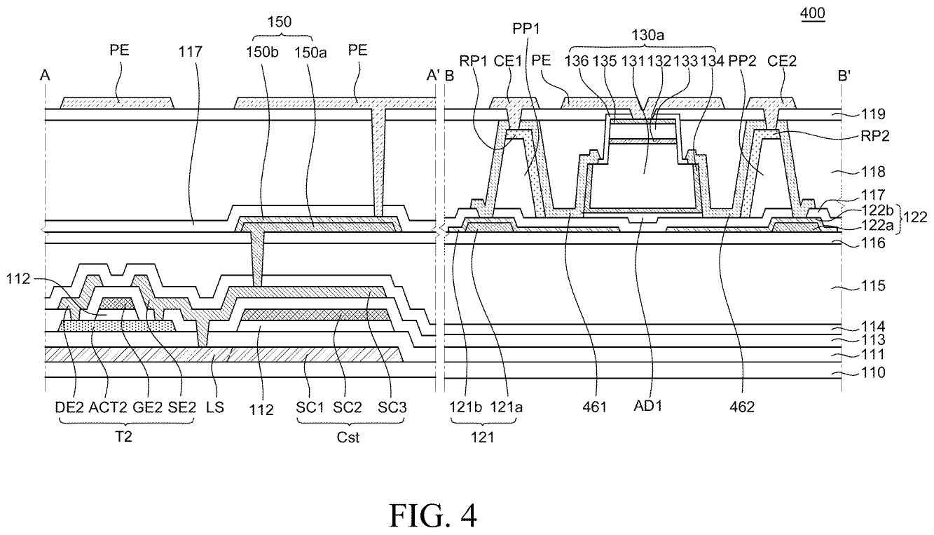

Hereinafter, a display device 400 according to another exemplary embodiment of the present disclosure will be described with reference to FIG. 4.

FIG. 4 is a cross-sectional view of a display device according to another exemplary embodiment of the present disclosure. The only difference between a display device 400 of FIG. 4 and the display device 100 of FIGS. 1 to 3B is a first contact electrode 461 and a second contact electrode 462, but the other configurations are substantially the same, so that a redundant description will be omitted.

Referring to FIG. 4, the first contact electrode 461 is disposed to extend from the side surface of the light emitting diode 130 and to pass over upper portions of the first reflective pattern RP1 and the first protrusion PP1 above the first assembly electrode 121 to be disposed at the outside of the first protrusion PP1. The second contact electrode 462 is disposed to extend from the side surface of the light emitting diode 130 and to pass over the second reflective pattern RP2 and the second protrusion PP2 above the second assembly electrode 122 to be disposed at the outside of the second protrusion PP2.

The first contact electrode 461 is in contact with the entire surface of the first reflective pattern RP1 and the second contact electrode 462 is in contact with the entire surface of the second reflective pattern RP2. That is, the first reflective pattern RP1 may be disposed so as not to be exposed from the first contact electrode 461 and the second reflective pattern RP2 may be disposed so as not to be exposed from the second contact electrode 462. Therefore, the first contact electrode 461 may be connected to the first reflective pattern RP1 and the second contact electrode 462 may be connected to the second reflective pattern RP2.

The reflectance of the first contact electrode 461 and the second contact electrode 462 may be equal to or higher than the reflectance of the first reflective pattern RP1 and the second reflective pattern RP2. That is, the first contact electrode 461 and the second contact electrode 462 may be formed of a reflective metal material having a reflectance equal to or higher than the reflectance of the first reflective pattern RP1 and the second reflective pattern RP2. Therefore, the first contact electrode 461 and the second contact electrode 462 may serve as reflectors which reflect light emitted from the light emitting diode 130 together with the first reflective pattern RP1 and the second reflective pattern RP2.

In the display device 400 according to another exemplary embodiment of the present disclosure, the contact electrodes 461 and 462 are connected to the reflective patterns RP1 and RP2 to reduce resistances of the wiring line and the electrode to which the low potential power voltage is applied.

Specifically, the first contact electrode 461 is in contact with the entire surface of the first reflective pattern RP1 and the second contact electrode 462 is in contact with the entire surface of the second reflective pattern RP2. That is, the first contact electrode 461 is connected to the first reflective pattern RP1 and the second contact electrode 462 is connected to the second reflective pattern RP2. Accordingly, the first contact electrode 461 and the second contact electrode 462 electrically connect the first assembly electrode 121 and the second assembly electrode 122 to the light emitting diode 130 and may also serve as reflectors which reflect light emitted from the light emitting diode 130. Further, the first contact electrode 461 and the second contact electrode 462 are connected to the first reflective pattern RP1 and the second reflective pattern RP2 so that the thickness may be increased as much as the thickness of the first reflective pattern RP1 and the second reflective pattern RP2. Therefore, the first contact electrode 461 and the second contact electrode 462 which are connected to the first reflective pattern RP1 and the second reflective pattern RP2 may reduce resistance for the low potential power voltage applied from the first assembly electrode 121 and the second assembly electrode 122. Accordingly, in the display device 400 according to another exemplary embodiment of the present disclosure, the contact electrodes 461 and 462 are connected to the reflective patterns RP1 and RP2 to reduce the resistances of the wiring line and the electrode to which the low potential power voltage is applied. Therefore, the power consumption of the display device 100 may be reduced.

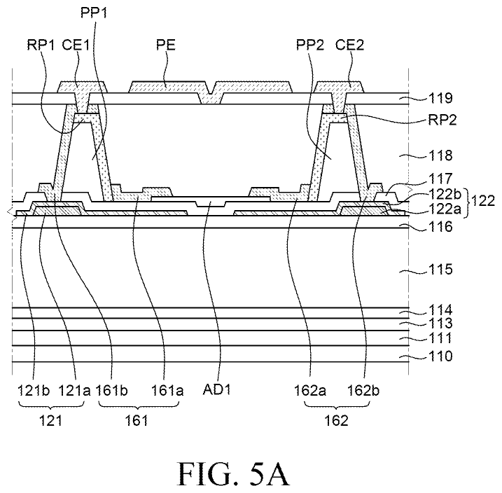

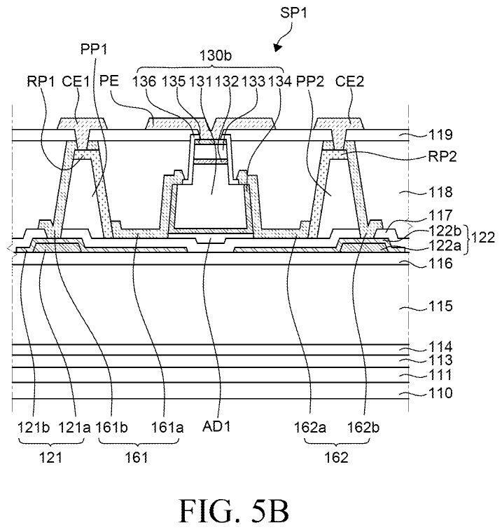

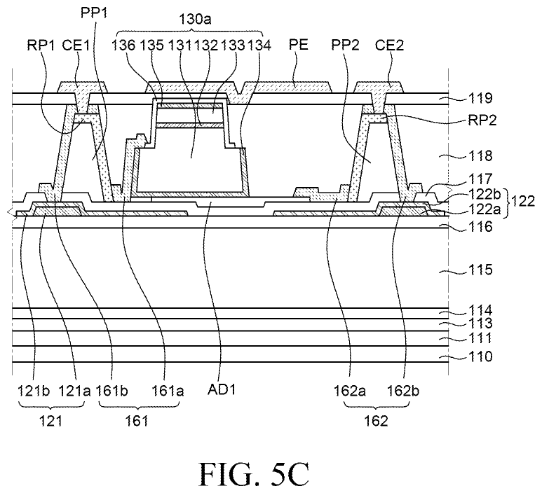

Hereinafter, a type of defective light emitting diodes will be described in detail with reference to FIGS. 5A to 5C.

FIG. 5A is a cross-sectional view of a display device according to Comparative Embodiment 1. FIG. 5B is a cross-sectional view of a display device according to Comparative Embodiment 2. FIG. 5C is a cross-sectional view of a display device according to Comparative Embodiment 3. FIGS. 5A to 5C are views for illustrating a light emitting diode in which defect occurs during a self-assembling process. In FIGS. 5A to 5C, for the convenience of description, only a cross-section of a sub pixel of a part in which a self-assembly defect of the light emitting diode occurs in the display device according to Comparative Embodiments 1 to 3 is illustrated.

First, referring to FIG. 5A, a sub pixel of a display device according to Comparative Embodiment 1 is a sub pixel in which a light emitting diode is not assembled during the self-assembling process. Accordingly, in the sub pixel of the display device according to Comparative Embodiment 1, even though electrodes and wiring lines are normally disposed other than the light emitting diode, there is no light emitting diode so that there may be a problem in that the sub pixel cannot emit light. Accordingly, in the sub pixel of the display device according to Comparative Embodiment 1, it may be necessary to repair the defect generated during the self-assembling process of the light emitting diode.

Referring to FIG. 5B, the display device according to Comparative Embodiment 2 is a display device in which a defect occurs by erroneously assembling a light emitting diode 130b which emits second color light, in a sub pixel SP1 which is defined to emit first color light, during the self-assembling process. Therefore, in the display device according to Comparative Embodiment 2, there may be a problem in that the sub pixel which is defined to emit first color light emits second color light. Accordingly, in the display device according to Comparative Embodiment 2, it may be necessary to repair the defect generated during the self-assembling process of the light emitting diode.

Referring to FIG. 5C, a sub pixel of a display device according to Comparative Embodiment 3 is a sub pixel having a defect in which the light emitting diode is misaligned during the self-assembling process of the light emitting diode. Therefore, in the sub pixel of the display device according to Comparative Embodiment 3, the light emitting diode is not electrically connected to the wiring line and the electrodes so that there may be a problem in that the light emitting diode does not emit light. Accordingly, in the sub pixel of the display device according to Comparative Embodiment 3, it may be necessary to repair the defect generated during the self-assembling process of the light emitting diode.

In the meantime, during the self-assembling process of the light emitting diode, even though the light emitting diode is normally assembled, the light emitting diode may not emit light due to the defect of the light emitting diode itself, in addition to the defects of the display device of Comparative Embodiments 1 to 3. A type of the defective light emitting diode is not limited thereto. Accordingly, in the display device in which the light emitting diode is self-assembled, it may be necessary to repair various defects generated during the self-assembling process of the light emitting diode.

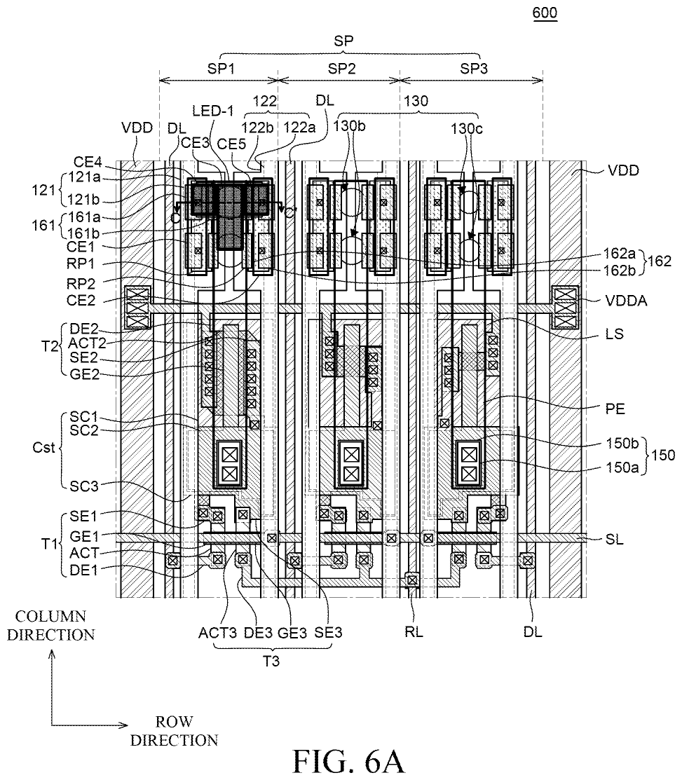

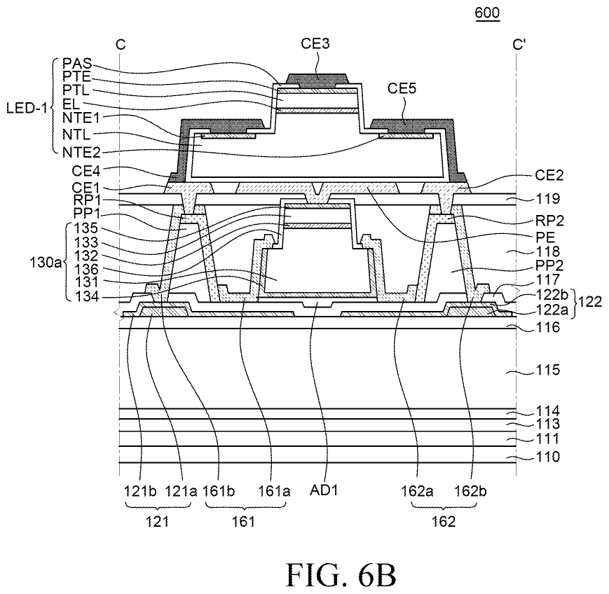

Hereinafter, a display device 600 according to still another exemplary embodiment of the present disclosure will be described with reference to FIGS. 6A and 6B.

FIG. 6A is an enlarged plan view of a display device according to still another exemplary embodiment of the present disclosure. FIG. 6B is a cross-sectional view taken along C-C′ of FIG. 6A. As compared with the display device 100 of FIGS. 1 to 3B, a display device 600 of FIGS. 6A and 6B further includes an additional light emitting diode LED-1, but other configurations are substantially the same, so that a redundant description will be omitted.

Referring to FIGS. 6A and 6B, an additional light emitting diode LED-1 is disposed on the first connection electrode CE1, the pixel electrode PE, and the second connection electrode CE2.

Referring to FIG. 6B, the additional light emitting diode LED-1 may be an NPN type light emitting diode with a lateral structure in which two n-type electrodes NTE1 and NTE2 are disposed on both sides of the p-type electrode PTE.

The additional light emitting diode LED-1 includes a first n-type electrode NTE1, a second n-type electrode NTE2, a first semiconductor layer NTL, an emission layer EL, a second semiconductor layer PTL, a p-type electrode PTE, and a passivation layer PAS.

The additional light emitting diode LED-1 may be formed by sequentially laminating the first semiconductor layer NTL, the emission layer EL, and the second semiconductor layer PTL, and then disposing the first n-type electrode NTE1 and the second n-type electrode NTE2 in a predetermined etched portion, and disposing the p-type electrode PTE on the second semiconductor layer PTL which is not etched. Therefore, in the additional light emitting diode LED-1, the p-type electrode may be disposed at a different height from that of the first n-type electrode NTE1 and the second n-type electrode NTE2.

The first semiconductor layer NTL and the second semiconductor layer PTL may be a layer formed by doping n-type and p-type impurities into a specific material. For example, the first semiconductor layer NTL may be formed by injecting the n-type impurity into gallium nitride (GaN) having excellent crystallinity, but is not limited thereto.

The first n-type electrode NTE1 and the second n-type electrode NTE2 are disposed in a portion formed by etching a part of the first semiconductor layer NTL. The first n-type electrode NTE1 and the second n-type electrode NTE2 are electrodes for electrically connecting the additional light emitting diode LED-1 and the assembly electrodes 121 and 122. The first n-type electrode NTE1 and the second n-type electrode NTE2 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof. However, they are not limited thereto.

The emission layer EL is disposed on a portion of the first semiconductor layer NTL which is not etched. For example, the emission layer EL is a layer of the additional light emitting diode LED-1 which emits light. For example, the emission layer EL may be configured by a nitride semiconductor such as indium nitride gallium (InGaN), but is not limited thereto.

The second semiconductor layer PTL is disposed on the emission layer EL. The second semiconductor layer PTL may be formed by injecting the p-type impurity into gallium nitride (GaN), but is not limited thereto.

The p-type electrode PTE is disposed on the second semiconductor layer PTL. The p-type electrode PTE is an electrode which electrically connects the pixel electrode PE and the additional light emitting diode LED-1. The p-type electrode PTE may be formed of a conductive material, for example, a transparent conductive material, such as indium tin oxide (ITO) or indium zinc oxide (IZO), but is not limited thereto.

The passivation layer PAS which encloses at least a part of the first semiconductor layer NTL, the emission layer EL, the second semiconductor layer PTL, the first n-type electrode NTE1, the p-type electrode PTE, and the second n-type electrode NTE2 is disposed. The passivation layer PAS is formed of an insulating material to protect the first semiconductor layer NTL, the emission layer EL, and the second semiconductor layer PTL. In the meantime, the first n-type electrode NTE1, the p-type electrode PTE, and the second n-type electrode NTE2 may be exposed from the passivation layer PAS. Therefore, the first connection electrode CE1, the second connection electrode CE2, and the pixel electrode PE may be electrically connected to a third connection electrode CE3, a fourth connection electrode CE4, and a fifth connection electrode CE5 to be described below.

The third connection electrode CE3, the fourth connection electrode CE4, and the fifth connection electrode CE5 are disposed on the additional light emitting diode LED-1. The third connection electrode CE3 electrically connects the p-type electrode PTE of the additional light emitting diode LED-1 and the pixel electrode PE, and the fourth connection electrode CE4 electrically connects the first n-type electrode NTE1 of the additional light emitting diode LED-1 and the first connection electrode CE1. Further, the fifth connection electrode CE5 electrically connects the second n-type electrode NTE2 of the additional light emitting diode LED-1 and the second connection electrode CE2. Therefore, the additional light emitting diode LED-1 may be electrically connected to the second transistor T2, the first assembly electrode 121, and the second assembly electrode 122.

The third connection electrode CE3 may extend from a top surface of the p-type electrode PTE exposed from the passivation layer PAS to a top surface of the pixel electrode PE. As described above, the pixel electrode PE is electrically connected to the second transistor T2. Therefore, the p-type electrode PTE may be electrically connected to the second transistor T2 through the third connection electrode CE3 and the pixel electrode PE.

The fourth connection electrode CE4 may extend from a top surface of the first n-type electrode NTE1 exposed from the passivation layer PAS to a top surface of the first connection electrode CE1. As described above, the first connection electrode CE1 is electrically connected to the first contact electrode 161 and the first contact electrode 161 is electrically connected to the first assembly electrode 121. Therefore, the first n-type electrode NTE1 may be electrically connected to the first assembly electrode 121 through the fourth connection electrode CE4, the first connection electrode CE1, and the first contact electrode 161.

The fifth connection electrode CE5 may extend from a top surface of the second n-type electrode NTE2 exposed from the passivation layer PAS to a top surface of the second connection electrode CE2. As described above, the second connection electrode CE2 is electrically connected to the second contact electrode 162 and the second contact electrode 162 is electrically connected to the second assembly electrode 122. Therefore, the second n-type electrode NTE2 is electrically connected to the second assembly electrode 122 through the fifth connection electrode CE5, the second connection electrode CE2, and the second contact electrode 162.

In the meantime, a direction of the third connection electrode CE3 which extends from the top surface of the p-type electrode PTE to the top surface of the pixel electrode PE may be perpendicular to a direction of the fourth connection electrode CE4 which extends from the top surface of the first n-type electrode NTE1 to the top surface of the first connection electrode CE1. A direction of the fourth connection electrode CE4 which extends from the top surface of the first n-type electrode NTE1 to the top surface of the first connection electrode CE1 may be disposed to be equal to a direction of the fifth connection electrode CE5 which extends from the top surface of the second n-type electrode NTE2 to the top surface of the second connection electrode CE2. However, it is not limited thereto.

The third connection electrode CE3, the fourth connection electrode CE4, and the fifth connection electrode CE5 may be configured by a conductive material, such as copper (Cu), aluminum (Al), molybdenum (Mo), nickel (Ni), titanium (Ti), chrome (Cr), or an alloy thereof, but are not limited thereto.

In the display device 600 according to still another exemplary embodiment of the present disclosure, the additional light emitting diode LED-1 is disposed on the first connection electrode CE1, the pixel electrode PE, and the second connection electrode CE2 to be configured to repair the defective light emitting diode above the fourth passivation layer 119.

Specifically, the first connection electrode CE1 and the second connection electrode CE2 disposed on the second planarization layer 118 and the fourth passivation layer 119 may be electrically connected to each of the first contact electrode 161 and the second contact electrode 162 through contact holes formed in the second planarization layer 118 and the fourth passivation layer 119. The first contact electrode 161 is electrically connected to the first assembly electrode 121 and the second connection electrode CE2 is electrically connected to the second assembly electrode 122. Accordingly, an electrical connection with the first assembly electrode 121 and the second assembly electrode 122 may be provided through the first connection electrode CE1 and the second connection electrode CE2, respectively. For example, when the defective light emitting diode 130 needs to be repaired, the additional light emitting diode LED-1 for repair is disposed on the first connection electrode CE1, the pixel electrode PE, and the second connection electrode CE2 disposed on the fourth passivation layer 119. Further, the first connection electrode CE1, the pixel electrode PE, and the second connection electrode CE2 and the first n-type electrode NTE1, the p-type electrode PTE, and the second n-type electrode NTE2 of the additional light emitting diode LED-1 are electrically connected to the third connection electrode CE3, the fourth connection electrode CE4, and the fifth connection electrode CE5. By doing this, the additional light emitting diode LED-1 and the first connection electrode CE1, the pixel electrode PE, and the second connection electrode CE2 may be electrically connected. Therefore, the defective light emitting diode may be repaired above the second planarization layer 118 and the fourth passivation layer 119 without adding a process of forming a separate contact hole in the second planarization layer 118 and the fourth passivation layer 119 for repairing the defective light emitting diode.

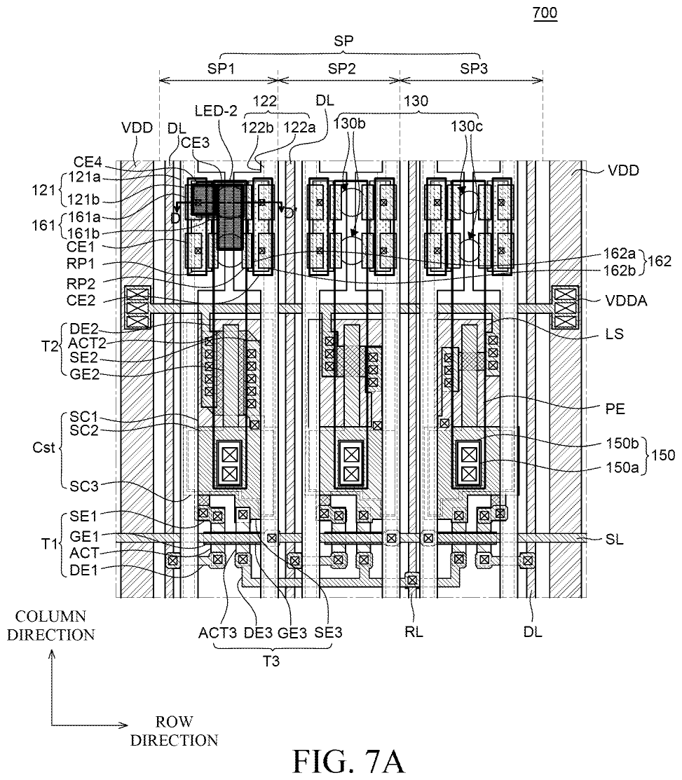

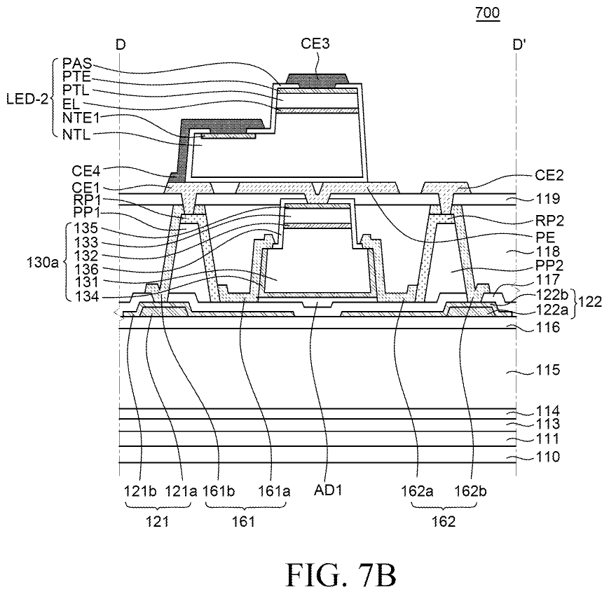

Hereinafter, a display device 700 according to still another exemplary embodiment of the present disclosure will be described with reference to FIGS. 7A and 7B.

FIG. 7A is an enlarged plan view of a display device according to still another exemplary embodiment of the present disclosure. FIG. 7B is a cross-sectional view taken along D-D′of FIG. 7A. As compared with the display device 100 of FIGS. 1 to 3B, a display device 700 of FIGS. 7A and 7B further disposes an additional light emitting diode LED-2, but other configurations are substantially the same, so that a redundant description will be omitted.

Referring to FIGS. 7A and 7B, an additional light emitting diode LED-2 is disposed on the first connection electrode CE1 or the second connection electrode CE2 and the pixel electrode PE.

Referring to FIG. 7B, the additional light emitting diode LED-2 may be a lateral type light emitting diode in which the first n-type electrode NTE1 and the p-type electrode PTE are disposed at different heights from each other.

The additional light emitting diode LED-2 includes a first n-type electrode NTE1, a first semiconductor layer NTL, an emission layer EL, a second semiconductor layer PTL, a p-type electrode PTE, and a passivation layer PAS.

The additional light emitting diode LED-2 is formed by sequentially laminating the first semiconductor layer NTL, the emission layer EL, and the second semiconductor layer PTL, and then disposing the first n-type electrode NTE1 in a predetermined etched portion, and disposing the p-type electrode PTE on the second semiconductor layer PTL which is not etched. Therefore, in the additional light emitting diode LED-2, the p-type electrode may be disposed at a different height from that of the first n-type electrode NTE1.

The first semiconductor layer NTL and the second semiconductor layer PTL may be a layer formed by doping n-type and p-type impurities into a specific material. For example, the first semiconductor layer NTL may be formed by injecting the n-type impurity into gallium nitride (GaN) having excellent crystallinity, but is not limited thereto.

The first n-type electrode NTE1 is disposed in a portion formed by etching a part of the first semiconductor layer NTL. The first n-type electrode NTE1 is an electrode which electrically connects one of the first connection electrode CE1 and the second connection electrode CE2 to the additional light emitting diode LED-2. The first n-type electrode NTE1 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

In the meantime, in FIGS. 7A and 7B, it is illustrated that the first n-type electrode NTE1 is disposed on the first connection electrode CE1 to be electrically connected to the first connection electrode CE1. However, the first n-type electrode NTE1 may also be disposed on the second connection electrode CE2 to be electrically connected to the second connection electrode CE2, but is not limited thereto. However, hereinafter, for the convenience of description, it is assumed that the first n-type electrode NTE1 is disposed on the first connection electrode CE1 to be electrically connected to the first connection electrode CE1.

The emission layer EL is disposed on a portion of the first semiconductor layer NTL which is not etched. For example, the emission layer EL is a layer of the additional light emitting diode LED-2 which emits light. For example, the emission layer EL may be configured by a nitride semiconductor such as indium nitride gallium (InGaN), but is not limited thereto.

The second semiconductor layer PTL is disposed on the emission layer EL. The second semiconductor layer PTL may be formed by injecting the p-type impurity into gallium nitride (GaN), but is not limited thereto.

The p-type electrode PTE is disposed on the second semiconductor layer PTL. The p-type electrode PTE is an electrode which electrically connects the pixel electrode PE and the additional light emitting diode LED-2. The p-type electrode PTE may be formed of a conductive material, for example, a transparent conductive material, such as indium tin oxide (ITO) or indium zinc oxide (IZO), but is not limited thereto.

The passivation layer PAS which encloses at least a part of the first semiconductor layer NTL, the emission layer EL, the second semiconductor layer PTL, the first n-type electrode NTE1, and the p-type electrode PTE is disposed. The passivation layer PAS is formed of an insulating material to protect the first semiconductor layer NTL, the emission layer EL, and the second semiconductor layer PTL. In the meantime, the first n-type electrode NTE1 and the p-type electrode PTE may be exposed from the passivation layer PAS. Therefore, the first connection electrode CE1 or the second connection electrode CE2 and the pixel electrode PE may be electrically connected to a third connection electrode CE3 and a fourth connection electrode CE4 to be described below.

The third connection electrode CE3 and the fourth connection electrode CE4 are disposed on the additional light emitting diode LED-2. The third connection electrode CE3 electrically connects the p-type electrode PTE of the additional light emitting diode LED-2 and the pixel electrode PE, and the fourth connection electrode CE4 electrically connects the first n-type electrode NTE1 of the additional light emitting diode LED-2 and the first connection electrode CE1 or the second connection electrode CE2. Therefore, the additional light emitting diode LED-2 may be electrically connected to the second transistor T2 and the first assembly electrode 121 or the second assembly electrode 122.

The third connection electrode CE3 may extend from a top surface of the p-type electrode PTE exposed from the passivation layer PAS to a top surface of the pixel electrode PE. As described above, the pixel electrode PE is electrically connected to the second transistor T2. Therefore, the p-type electrode PTE may be electrically connected to the second transistor T2 through the third connection electrode CE3 and the pixel electrode PE.

For example, the fourth connection electrode CE4 may extend from a top surface of the first n-type electrode NTE1 exposed from the passivation layer PAS to a top surface of the first connection electrode CE1. As described above, the first connection electrode CE1 is electrically connected to the first contact electrode 161 and the first contact electrode 161 is electrically connected to the first assembly electrode 121. Therefore, the first n-type electrode NTE1 may be electrically connected to the first assembly electrode 121 through the fourth connection electrode CE4, the first connection electrode CE1, and the first contact electrode 161.

In the meantime, a direction of the third connection electrode CE3 which extends from the top surface of the p-type electrode PTE to the top surface of the pixel electrode PE may be perpendicular to a direction of the fourth connection electrode CE4 which extends from the top surface of the first n-type electrode NTE1 to the top surface of the first connection electrode CE1. However, it is not limited thereto.

The third connection electrode CE3 and the fourth connection electrode CE4, for example, may be configured by a conductive material, such as copper (Cu), aluminum (Al), molybdenum (Mo), nickel (Ni), titanium (Ti), chrome (Cr), or an alloy thereof, but are not limited thereto.

In the display device 700 according to still another exemplary embodiment of the present disclosure, the additional light emitting diode LED-2 is disposed on the first connection electrode CE1 and the pixel electrode PE to be configured to repair the defective light emitting diode above the fourth passivation layer 119.

Specifically, the first connection electrode CE1 disposed on the second planarization layer 118 and the fourth passivation layer 119 may be electrically connected to the first contact electrode 161 through a contact hole formed in the second planarization layer 118 and the fourth passivation layer 119. The first contact electrode 161 is electrically connected to the first assembly electrode 121. Accordingly, an electrical connection with the first assembly electrode 121 may be provided through the first connection electrode CE1. For example, when the defective light emitting diode 130 needs to be repaired, the additional light emitting diode LED-2 for repair is disposed on the first connection electrode CE1 and the pixel electrode PE disposed on the fourth passivation layer 119. Further, the first connection electrode CE1 and the pixel electrode PE and the first n-type electrode NTE1 and the p-type electrode PTE of the additional light emitting diode LED-2 are electrically connected to the third connection electrode CE3 and the fourth connection electrode CE4. By doing this, the additional light emitting diode LED-2 and the first connection electrode CE1 and the pixel electrode PE may be electrically connected. Therefore, the defective light emitting diode may be repaired above the second planarization layer 118 and the fourth passivation layer 119 without adding a process of forming a separate contact hole in the second planarization layer 118 and the fourth passivation layer 119 for repairing the defective light emitting diode.

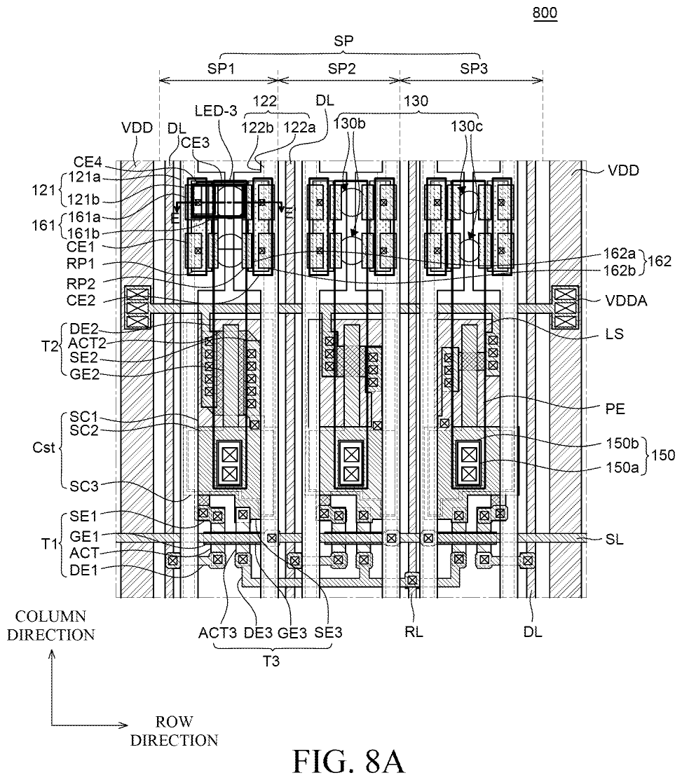

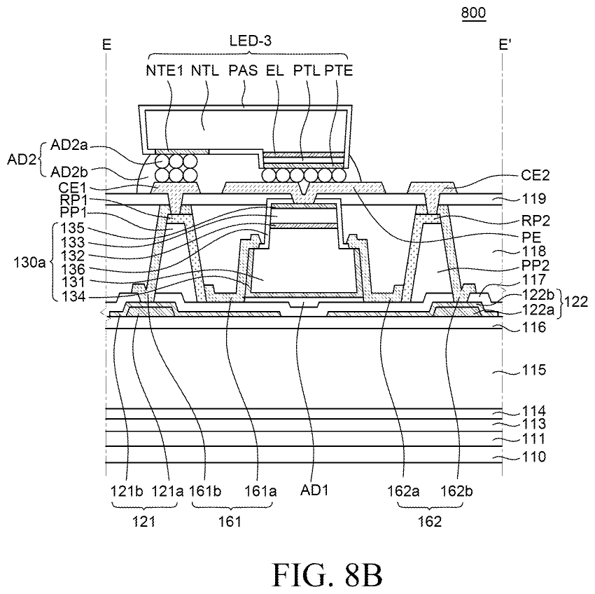

Hereinafter, a display device 800 according to still another exemplary embodiment of the present disclosure will be described with reference to FIGS. 8A and 8B.

FIG. 8A is an enlarged plan view of a display device according to still another exemplary embodiment of the present disclosure. FIG. 8B is a cross-sectional view taken along E-E′ of FIG. 8A. As compared with the display device 100 of FIGS. 1 to 3B, a display device 800 of FIGS. 8A and 8B further includes an additional light emitting diode LED-3, but other configurations are substantially the same, so that a redundant description will be omitted.

Referring to FIGS. 8A and 8B, an additional light emitting diode LED-3 is disposed on the first connection electrode CE1 or the second connection electrode CE2 and the pixel electrode PE.

Referring to FIG. 8B, the additional light emitting diode LED-3 may be a flip-chip type light emitting diode which is disposed on the first connection electrode CE1 or the second connection electrode CE2 and the pixel electrode PE in a flip-chip manner.

The additional light emitting diode LED-3 includes a first n-type electrode NTE1, a first semiconductor layer NTL, an emission layer EL, a second semiconductor layer PTL, a p-type electrode PTE, and a passivation layer PAS.

The additional light emitting diode LED-3 may be formed by sequentially laminating the first semiconductor layer NTL, the emission layer EL, and the second semiconductor layer PTL, and then disposing the first n-type electrode NTE1 in a predetermined etched portion, and disposing the p-type electrode PTE on the second semiconductor layer PTL which is not etched. Therefore, in the additional light emitting diode LED-3, the p-type electrode may be disposed at a different height from that of the first n-type electrode NTE1, but is not limited thereto.

The first semiconductor layer NTL and the second semiconductor layer PTL may be a layer formed by doping n-type and p-type impurities into a specific material. For example, the first semiconductor layer NTL may be formed by injecting the n-type impurity into gallium nitride (GaN) having excellent crystallinity, but is not limited thereto.

The first n-type electrode NTE1 is disposed in a portion formed by etching a part of the first semiconductor layer NTL. The first n-type electrode NTE1 is an electrode for electrically connecting one of the first connection electrode CE1 and the second connection electrode CE2 to the additional light emitting diode LED-3. The first n-type electrode NTE1 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

In the meantime, in FIGS. 8A and 8B, it is illustrated that the first n-type electrode NTE1 is disposed on the first connection electrode CE1 to be electrically connected to the first connection electrode CE1. However, the first n-type electrode may also be disposed on the second connection electrode CE2 to be electrically connected to the second connection electrode CE2, but is not limited thereto. However, hereinafter, for the convenience of description, it is assumed that the first n-type electrode NTE1 is disposed on the first connection electrode CE1 to be electrically connected to the first connection electrode CE1.

The emission layer EL is disposed on a portion of the first semiconductor layer NTL which is not etched. The emission layer EL is a layer of the additional light emitting diode LED-3 which emits light. For example, the emission layer EL may be configured by a nitride semiconductor such as indium nitride gallium (InGaN), but is not limited thereto.

The second semiconductor layer PTL is disposed on the emission layer EL. The second semiconductor layer PTL may be formed by injecting the p-type impurity into gallium nitride (GaN), but is not limited thereto.

The p-type electrode PTE is disposed on the second semiconductor layer PTL. The p-type electrode PTE is an electrode which electrically connects the pixel electrode PE and the additional light emitting diode LED-3. The p-type electrode PTE may be formed of a conductive material, for example, a transparent conductive material, such as indium tin oxide (ITO) or indium zinc oxide (IZO), but is not limited thereto.

A passivation layer PAS which encloses at least a part of the first semiconductor layer NTL, the emission layer EL, the second semiconductor layer PTL, the first n-type electrode NTE1, and the p-type electrode PTE is disposed. The passivation layer PAS is formed of an insulating material to protect the first semiconductor layer NTL, the emission layer EL, and the second semiconductor layer PTL. In the meantime, the first n-type electrode NTE1 and the p-type electrode PTE may be exposed from the passivation layer PAS. Therefore, the first connection electrode CE1 or the second connection electrode CE2 and the pixel electrode PE may be electrically connected to a conductive adhesive layer AD2 to be described below.

The conductive adhesive layer AD2 is disposed between the first connection electrode CE1 or the second connection electrode CE2 and the pixel electrode PE disposed on the planarization layer and the additional light emitting diode LED-3.

The conductive adhesive layer AD2 may be a conductive adhesive layer in which conductive balls AD2a are dispersed in a base member AD2b. Therefore, when heat or pressure is applied to the conductive adhesive layer AD2, the conductive balls AD2a are electrically connected in a portion applied with the heat or pressure to have a conductive property.

The conductive balls AD2a are mixed in the base member AD2b and for example, may serve to electrically connect the first n-type electrode NTE1, and the p-type electrode PTE of the additional light emitting diode LED-3 and the first connection electrode CE1 and the pixel electrode PE when the first n-type electrode NTE1, and the p-type electrode PTE of the additional light emitting diode LED-3 and the first connection electrode CE1 and the pixel electrode PE are bonded. For example, the conductive balls AD2a may be configured of a conductive material having a ductility, such as gold (Au), in a material such as nickel (Ni), but are not limited thereto.

The base member AD2b may be an adhesive member having adhesiveness and insulating property. For example, the base member AD2b may be a thermosetting adhesive, but is not limited thereto.

Referring to FIG. 8B, the first n-type electrode NTE1 is electrically connected to the first connection electrode CE1 through the conductive adhesive layer AD2 and the p-type electrode PTE is electrically connected to the pixel electrode PE through the conductive adhesive layer AD2. For example, after applying a conductive adhesive layer AD2 in which the conductive balls AD2a are mixed on the first connection electrode CE1 and the pixel electrode PE in an inkjet manner, the additional light emitting diode LED-3 is transferred onto the conductive adhesive layer AD2 and the additional light emitting diode LED-3 is pressurized and heated. By doing this, the first n-type electrode NTE1 and the p-type electrode PTE and the first connection electrode CE1 and the pixel electrode PE may be electrically connected, respectively, by means of the conductive balls AD2a.

In the meantime, the conductive balls AD2a may be induced to be disposed only between the first n-type electrode NTE1 and the first connection electrode CE1 and between the p-type electrode PTE and the pixel electrode PE. Further, the other part of the conductive adhesive layer AD2 excluding a part in which the conductive balls AD2a are disposed has an insulating property. However, the conductive adhesive layer AD2 may be separated to be disposed between the first n-type electrode NTE1 and the first connection electrode CE1 and between the p-type electrode PTE and the pixel electrode PE, respectively, but is not limited thereto.

In the display device 800 according to still another exemplary embodiment of the present disclosure, the additional light emitting diode LED-3 is disposed on the first connection electrode CE1 and the pixel electrode PE to be configured to repair the defective light emitting diode above the fourth passivation layer 119.

Specifically, the first connection electrode CE1 disposed on the second planarization layer 118 and the fourth passivation layer 119 may be electrically connected to the first contact electrode 161 through a contact hole formed in the second planarization layer 118 and the fourth passivation layer 119. The first contact electrode 161 is electrically connected to the first assembly electrode 121. Accordingly, an electrical connection with the first assembly electrode 121 may be provided through the first connection electrode CE1. For example, when the defective light emitting diode 130 needs to be repaired, the conductive adhesive layer AD2 is disposed on the first connection electrode CE1 and the pixel electrode PE disposed on the fourth passivation layer 119 and the additional light emitting diode LED-3 for repair is transferred onto the conductive adhesive layer AD2. Further, the additionally light emitting diode LED-3 is pressurized and heated to electrically connect the first connection electrode CE1 and the pixel electrode PE and the first n-type electrode NTE1 and the p-type electrode PTE2 of the additional light emitting diode LED-2 through the conductive adhesive layer AD2. Therefore, the defective light emitting diode may be repaired above the second planarization layer 118 and the fourth passivation layer 119 without adding a process of forming a separate contact hole in the second planarization layer 118 and the fourth passivation layer 119 for repairing the defective light emitting diode.

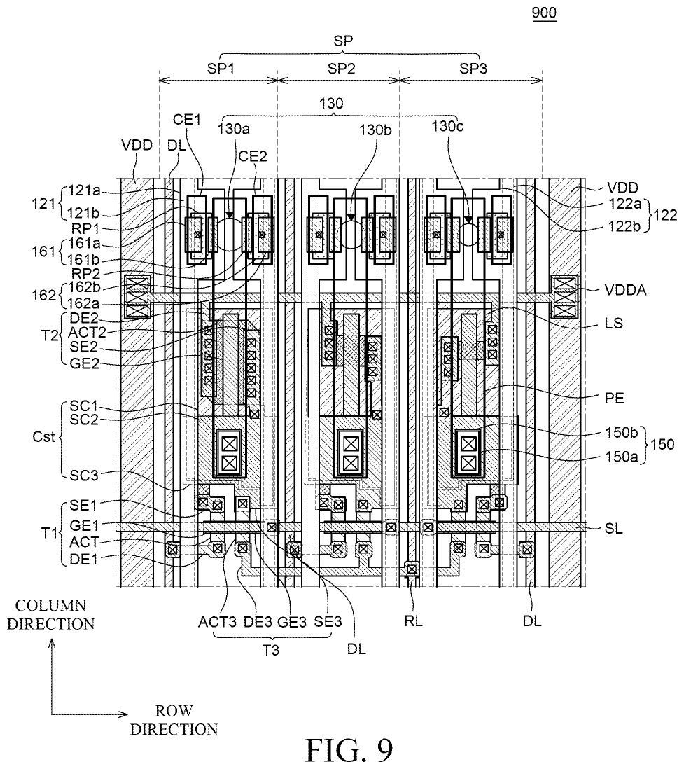

Hereinafter, a display device 900 according to still another exemplary embodiment of the present disclosure will be described with reference to FIG. 9.

FIG. 9 is an enlarged plan view of a display device according to still another exemplary embodiment of the present disclosure. The only difference between a display device 900 of FIG. 9 and the display device 100 of FIGS. 1 to 3B is that only one light emitting diode 130 is disposed in one sub pixel SP, but the other configurations are substantially the same, so that a redundant description will be omitted.

Referring to FIG. 9, in the display device 900 according to still another exemplary embodiment of the present disclosure, only one light emitting diode 130 may be disposed in one sub pixel SP. That is, the placement of the redundancy light emitting diode which is further disposed on the same plane as the light emitting diode 130 of one sub pixel SP for repairing the defective light emitting diode may be omitted. Therefore, a space for disposing the redundancy light emitting diode is omitted so that a display device 900 with a high resolution may be implemented.

Specifically, in the display device 900 according to still another exemplary embodiment of the present disclosure, the redundancy additional light emitting diodes LED-1, LED-2, and LED-3 may be disposed above the light emitting diode 130. Accordingly, the defective light emitting diode may be repaired above the second planarization layer 118 and the fourth passivation layer 119 without adding a process of forming a separate contact hole in the second planarization layer 118 and the fourth passivation layer 119 for repairing the defective light emitting diode. Further, the redundancy additional light emitting diodes LED-1, LED-2, and LED-3 are disposed above the light emitting diode 130 so that an extra light emitting diode to be further disposed for the redundancy may not be disposed in one sub pixel SP. Therefore, the space for disposing the redundancy light emitting diode is omitted so that more sub pixels SP may be disposed in the same space on the substrate 110 and the display device 900 with a high resolution may be implemented. Accordingly, in the display apparatus 900 according to the exemplary embodiment of the present disclosure, a space for disposing a redundancy light emitting diode is omitted so that the display device 900 with a high resolution may be implemented.

The exemplary embodiments of the present disclosure can also be described as follows:

According to an aspect of the present disclosure, a display device includes a substrate including a plurality of sub pixels; a first assembly electrode and a second assembly electrode which are disposed on each of the plurality of sub pixels and are spaced apart from each other; a first protrusion and a second protrusion disposed on the first assembly electrode and the second assembly electrode; a light emitting diode disposed between the first protrusion and the second protrusion; a first reflective pattern which is disposed on a side surface of the first protrusion opposite to the light emitting diode; a second reflective pattern which is disposed on a side surface of the second protrusion opposite to the light emitting diode; a first contact electrode which is disposed on the first protrusion and the first reflective pattern and is electrically connected to the first assembly electrode; and a second contact electrode which is disposed on the second protrusion and the second reflective pattern and is electrically connected to the second assembly electrode.

The first assembly electrode and the second assembly electrode may be low potential power lines.

A side surface of the first protrusion on which the first reflective pattern is disposed and a side surface of the second protrusion on which the second reflective pattern is disposed may be inclined surfaces.

The display device may further comprise a passivation layer disposed on the first assembly electrode and the second assembly electrode.

The first contact electrode may be electrically connected to the first assembly electrode through a contact hole of the passivation layer disposed at the outside of the first protrusion and the second contact electrode may be electrically connected to the second assembly electrode through a contact hole of the passivation layer disposed at the outside of the second protrusion.

The light emitting diode may include a first electrode, a first semiconductor layer, an emission layer, a second semiconductor layer, and a second electrode.

The first contact electrode and the second contact electrode may be in contact with the first electrode.

The first contact electrode may include a first part which is in contact with the first reflective pattern and the first electrode, and a second part which is spaced apart from the first part and is in contact with the first assembly electrode and the first reflective pattern.

The second contact electrode may include a first part which is in contact with the second reflective pattern and the first electrode, and a second part which is spaced apart from the first part and is in contact with the second assembly electrode and the second reflective pattern.

A reflectance of the first contact electrode and the second contact electrode may be lower than the reflectance of the first reflective pattern and the second reflective pattern.

The first contact electrode may be in contact with the entire surface of the first reflective pattern.

The second contact electrode may be in contact with the entire surface of the second reflective pattern.

The reflectance of the first contact electrode and the second contact electrode may be equal to or higher than the reflectance of the first reflective pattern and the second reflective pattern.

The display device may further comprise a planarization layer disposed on the first protrusion, the second protrusion, the light emitting diode, the first contact electrode, and the second contact electrode; a pixel electrode which is disposed on the planarization layer and is electrically connected to the light emitting diode; a first connection electrode which is disposed on the planarization layer and is electrically connected to the first contact electrode; and a second connection electrode which is disposed on the planarization layer and is electrically connected to the second contact electrode.

The display device may further comprise an additional light emitting diode which is disposed on the planarization layer and includes a first n-type electrode, a first semiconductor layer, an emission layer, a second semiconductor layer, and a p-type electrode.

The p-type electrode may be electrically connected to the pixel electrode and the first n-type electrode may be electrically connected to one of the first connection electrode and the second connection electrode.

The display device may further comprise a conductive adhesive layer disposed between the additional light emitting diode and the planarization layer.

The additional light emitting diode may be a flip chip type light emitting diode.

The display device may further comprise a third connection electrode which electrically connects the p-type electrode and the pixel electrode; and a fourth connection electrode which connects the first n-type electrode to the first connection electrode or the second connection electrode.

The additional light emitting diode may be a lateral type light emitting diode.

The display device may further comprise an additional light emitting diode which is disposed on the planarization layer and includes a first n-type electrode, a second n-type electrode, a first semiconductor layer, an emission layer, a second semiconductor layer, and a p-type electrode; a third connection electrode which electrically connects the p-type electrode and the pixel electrode; a fourth connection electrode which electrically connects the first n-type electrode and the first connection electrode; and a fifth connection electrode which electrically connects the second n-type electrode and the second connection electrode.

According to another aspect of the present disclosure, a display device includes a substrate including a plurality of sub pixels; a first assembly electrode and a second assembly electrode which are disposed on each of the plurality of sub pixels and are spaced apart from each other; a first protrusion which is disposed on the first assembly electrode and includes a top surface and a side surface disposed on a different plane from the top surface; a second protrusion which is disposed on the second assembly electrode and includes a top surface and a side surface disposed on a different plane from the top surface; a light emitting diode disposed between the first protrusion and the second protrusion; a first reflective pattern disposed on a side surface of the first protrusion; a second reflective pattern disposed on a side surface of the second protrusion; a first contact electrode which is disposed on the first protrusion and the first reflective pattern and is electrically connected to the first assembly electrode; and a second contact electrode which is disposed on the second protrusion and the second reflective pattern and is electrically connected to the second assembly electrode. The side surface of the first protrusion on which the first reflective pattern is disposed and the side surface of the second protrusion on which the second reflective pattern is disposed are opposite to the light emitting diode.

The first contact electrode may include a first part which is in contact with the first reflective pattern and the first electrode of the light emitting diode, and a second part which is spaced apart from the first part and is in contact with the first assembly electrode and the first reflective pattern.

The second contact electrode may include a first part which is in contact with the second reflective pattern and the first electrode of the light emitting diode, and a second part which is spaced apart from the first part and is in contact with the second assembly electrode and the second reflective pattern.

The first contact electrode may be in contact with the entire surface of the first reflective pattern and the second contact electrode may be in contact with the entire surface of the second reflective pattern.

The display device may further comprise a planarization layer disposed on the first protrusion, the second protrusion, the light emitting diode, the first contact electrode, and the second contact electrode; a pixel electrode which is disposed on the planarization layer and is electrically connected to the first electrode of the light emitting diode; a first connection electrode which is disposed on the planarization layer and is electrically connected to the first contact electrode; and a second connection electrode which is disposed on the planarization layer and is electrically connected to the second contact electrode.

The display device may further comprise an additional light emitting diode which is disposed on the planarization layer and includes a first n-type electrode, a first semiconductor layer, an emission layer, a second semiconductor layer, and a p-type electrode; a third connection electrode which electrically connects the p-type electrode and the pixel electrode; and a fourth connection electrode which connects the first n-type electrode to the first connection electrode or the second connection electrode.

The additional light emitting diode may be a lateral type light emitting diode.

The display device may further comprise an additional light emitting diode which is disposed on the planarization layer and includes a first n-type electrode, a first semiconductor layer, an emission layer, a second semiconductor layer, and a p-type electrode; and a conductive adhesive layer disposed between the additional light emitting diode and the planarization layer.

The additional light emitting diode may be a flip chip type light emitting diode.

The display device may further comprise an additional light emitting diode which is disposed on the planarization layer and includes a first n-type electrode, a second n-type electrode, a first semiconductor layer, an emission layer, a second semiconductor layer, and a p-type electrode; a third connection electrode which electrically connects the p-type electrode and the pixel electrode; a fourth connection electrode which electrically connects the first n-type electrode and the first connection electrode; and a fifth connection electrode which electrically connects the second n-type electrode and the second connection electrode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a plurality of sub pixels;
a first assembly electrode and a second assembly electrode which are disposed on each of the plurality of sub pixels and are spaced apart from each other;
a first protrusion and a second protrusion disposed on the first assembly electrode and the second assembly electrode, respectively, the first protrusion having a side surface and the second protrusion having a side surface;
a light emitting diode disposed between the first protrusion and the second protrusion;
a first reflective pattern which is disposed on the side surface of the first protrusion opposite to the light emitting diode;
a second reflective pattern which is disposed on the side surface of the second protrusion opposite to the light emitting diode;
a first contact electrode which is disposed on the first protrusion and the first reflective pattern and is electrically connected to the first assembly electrode; and
a second contact electrode which is disposed on the second protrusion and the second reflective pattern and is electrically connected to the second assembly electrode.

2. The display device according to claim 1, wherein the first assembly electrode and the second assembly electrode are low potential power lines.

3. The display device according to claim 1, wherein the side surface of the first protrusion on which the first reflective pattern is disposed and the side surface of the second protrusion on which the second reflective pattern is disposed are inclined surfaces.

4. The display device according to claim 1, further comprising:
a passivation layer disposed on the first assembly electrode and the second assembly electrode,
wherein the first contact electrode is electrically connected to the first assembly electrode through a contact hole of the passivation layer disposed at the outside of the first protrusion and the second contact electrode is electrically connected to the second assembly electrode through a contact hole of the passivation layer disposed at the outside of the second protrusion.

5. The display device according to claim 4, wherein the light emitting diode includes a first electrode, a first semiconductor layer, an emission layer, a second semiconductor layer, and a second electrode, and
wherein the first contact electrode and the second contact electrode are in contact with the first electrode.

6. The display device according to claim 5, wherein the first contact electrode includes a first part which is in contact with the first reflective pattern and the first electrode, and a second part which is spaced apart from the first part and is in contact with the first assembly electrode and the first reflective pattern, and
wherein the second contact electrode includes a first part which is in contact with the second reflective pattern and the first electrode, and a second part which is spaced apart from the first part and is in contact with the second assembly electrode and the second reflective pattern.

7. The display device according to claim 6, wherein a reflectance of the first contact electrode and the second contact electrode is lower than the reflectance of the first reflective pattern and the second reflective pattern.

8. The display device according to claim 5, wherein the first contact electrode is in contact with the entire surface of the first reflective pattern and
wherein the second contact electrode is in contact with the entire surface of the second reflective pattern.

9. The display device according to claim 8, wherein the reflectance of the first contact electrode and the second contact electrode is equal to or higher than the reflectance of the first reflective pattern and the second reflective pattern.

10. The display device according to claim 1, further comprising:
a planarization layer disposed on the first protrusion, the second protrusion, the light emitting diode, the first contact electrode, and the second contact electrode;
a pixel electrode which is disposed on the planarization layer and is electrically connected to the light emitting diode;
a first connection electrode which is disposed on the planarization layer and is electrically connected to the first contact electrode; and
a second connection electrode which is disposed on the planarization layer and is electrically connected to the second contact electrode.

11. The display device according to claim 10, further comprising:
an additional light emitting diode which is disposed on the planarization layer and includes a first n-type electrode, a first semiconductor layer, an emission layer, a second semiconductor layer, and a p-type electrode,
wherein the p-type electrode is electrically connected to the pixel electrode and the first n-type electrode is electrically connected to one of the first connection electrode and the second connection electrode.

12. The display device according to claim 11, further comprising:
a conductive adhesive layer disposed between the additional light emitting diode and the planarization layer,
wherein the additional light emitting diode includes a flip chip type light emitting diode.

13. The display device according to claim 11, further comprising:
a third connection electrode which electrically connects the p-type electrode and the pixel electrode; and
a fourth connection electrode which electrically connects the first n-type electrode to the first connection electrode or the second connection electrode,
wherein the additional light emitting diode includes a lateral type light emitting diode.

14. The display device according to claim 10, further comprising:
an additional light emitting diode which is disposed on the planarization layer and includes a first n-type electrode, a second n-type electrode, a first semiconductor layer, an emission layer, a second semiconductor layer, and a p-type electrode;
a third connection electrode which electrically connects the p-type electrode and the pixel electrode;
a fourth connection electrode which electrically connects the first n-type electrode and the first connection electrode; and
a fifth connection electrode which electrically connects the second n-type electrode and the second connection electrode.

15. A display device, comprising:
a substrate including a plurality of sub pixels;
a first assembly electrode and a second assembly electrode which are disposed on each of the plurality of sub pixels and are spaced apart from each other;
a first protrusion which is disposed on the first assembly electrode and includes a top surface and a side surface disposed on a different plane from the top surface, the side surface of the first protrusion extends from the top surface of the first protrusion;
a second protrusion which is disposed on the second assembly electrode and includes a top surface and a side surface disposed on a different plane from the top surface, the side surface of the second protrusion extends from the top surface of the second protrusion;
a light emitting diode disposed between the first protrusion and the second protrusion;
a first reflective pattern disposed on the side surface of the first protrusion;
a second reflective pattern disposed on the side surface of the second protrusion;
a first contact electrode which is disposed on the first protrusion and the first reflective pattern and is electrically connected to the first assembly electrode; and
a second contact electrode which is disposed on the second protrusion and the second reflective pattern and is electrically connected to the second assembly electrode,
wherein the side surface of the first protrusion on which the first reflective pattern is disposed and the side surface of the second protrusion on which the second reflective pattern is disposed are opposite to the light emitting diode.

16. The display device according to claim 15, wherein the first contact electrode includes a first part which is in contact with the first reflective pattern and the first electrode of the light emitting diode, and a second part which is spaced apart from the first part and is in contact with the first assembly electrode and the first reflective pattern, and
wherein the second contact electrode includes a first part which is in contact with the second reflective pattern and the first electrode of the light emitting diode, and a second part which is spaced apart from the first part and is in contact with the second assembly electrode and the second reflective pattern.

17. The display device according to claim 15, wherein the first contact electrode is in contact with the entire surface of the first reflective pattern and
wherein the second contact electrode is in contact with the entire surface of the second reflective pattern.

18. The display device according to claim 15, further comprising:
a planarization layer disposed on the first protrusion, the second protrusion, the light emitting diode, the first contact electrode, and the second contact electrode;
a pixel electrode which is disposed on the planarization layer and is electrically connected to the first electrode of the light emitting diode;
a first connection electrode which is disposed on the planarization layer and is electrically connected to the first contact electrode; and
a second connection electrode which is disposed on the planarization layer and is electrically connected to the second contact electrode.

19. The display device according to claim 18, further comprising:
an additional light emitting diode which is disposed on the planarization layer and includes a first n-type electrode, a first semiconductor layer, an emission layer, a second semiconductor layer, and a p-type electrode;
a third connection electrode which electrically connects the p-type electrode and the pixel electrode; and
a fourth connection electrode which connects the first n-type electrode to the first connection electrode or the second connection electrode,
wherein the additional light emitting diode includes a lateral type light emitting diode.

20. The display device according to claim 18, further comprising:
an additional light emitting diode which is disposed on the planarization layer and includes a first n-type electrode, a first semiconductor layer, an emission layer, a second semiconductor layer, and a p-type electrode; and
a conductive adhesive layer disposed between the additional light emitting diode and the planarization layer,
wherein the additional light emitting diode includes a flip chip type light emitting diode.

21. The display device according to claim 18, further comprising:
an additional light emitting diode which is disposed on the planarization layer and includes a first n-type electrode, a second n-type electrode, a first semiconductor layer, an emission layer, a second semiconductor layer, and a p-type electrode;
a third connection electrode which electrically connects the p-type electrode and the pixel electrode;
a fourth connection electrode which electrically connects the first n-type electrode and the first connection electrode; and
a fifth connection electrode which electrically connects the second n-type electrode and the second connection electrode.
